(19) United States
(12) Patent Application Publication
(10) Pub. No.: US 2025/0313722 A1
(43) Pub. Date: Oct. 9, 2025

(54) CHEMICAL MECHANICAL POLISHING SLURRY COMPOSITION AND METHOD FOR MANUFACTURING SEMICONDUCTOR DEVICE

(71) Applicant: SOULBRAIN CO., LTD., Seongnam-si (KR)

(72) Inventors: Jeong Ho LEE, Seongnam-si (KR); Seok Joo KIM, Seongnam-si (KR)

(21) Appl. No.: 19/191,233

(22) Filed: Apr. 28, 2025

Related U.S. Application Data
(63) Continuation of application No. PCT/KR2023/017048, filed on Oct. 30, 2023.

(30) Foreign Application Priority Data
Oct. 28, 2022 (KR) 10-2022-0141451

(51) Int. Cl. C09G 1/02; H01L 21/3105

(52) U.S. Cl. CPC C09G 1/02; H01L 21/31053

(57) ABSTRACT

Cerium oxide particles for chemical mechanical polishing and a chemical mechanical polishing slurry composition containing same are described. The characteristic cerium oxide particles can be combined with a surface treatment agent to change the zeta potential of the surface of the cerium oxide particles while maintaining monodispersity and a high oxide film polishing speed, and thereby provide a chemical mechanical polishing slurry composition that can be used for various purposes during the STI process, and a method for manufacturing a semiconductor device using the chemical mechanical polishing slurry composition.

### CROSS REFERENCE TO RELATED APPLICATION

The present application is a Continuation of PCT/KR2023/017048 filed on Oct. 30, 2023, which claims priority to Korean Patent Application No. 10-2022-0141451, filed Oct. 28, 2022, the entire contents of which are incorporated here for all purposes by this reference.

### TECHNICAL FIELD

The present invention relates to a chemical mechanical polishing slurry composition including cerium oxide particles and a method of manufacturing a semiconductor device, and more specifically, to a chemical mechanical polishing slurry composition enabling to obtain cerium oxide particles by a synthetic method different from existing cerium oxide particles so that the proportion of Ce³⁺ on the surface of cerium oxide increases to have a high oxide film removal rate at a low content despite a small particle size, and in combination with this, through an appropriate additive component, to convert the zeta potential of the cerium oxide particle surface to enable the slurry to be applicable to various polishing processes, and a method for manufacturing a semiconductor device using the same.

### BACKGROUND ART

As semiconductor devices are more diversified and highly integrated, finer pattern formation technologies are being used, and accordingly, the surface structure of semiconductor devices is becoming more complex, and the interlayer planarity in each process is becoming a critical factor in improving the precision of photolithography. In manufacturing semiconductor devices, a chemical mechanical polishing (CMP) process is used as a planarization technology. For example, CMP is widely used as a process for removing an insulating film excessively deposited for interlayer insulation, a process for planarizing an insulating film for shallow trench isolation (STI) that provides insulation between interlayer dielectronics and chips, and a process for forming metal conductive films such as wiring, contact plugs, and via contacts.

In the CMP process, the polishing rate, the planarity of the polished surface, and the degree of scratch occurrence are important, and they are determined by the CMP process conditions, the type of slurry, and the type of polishing pad. High-purity cerium oxide particles are used in cerium oxide slurries. Recently, in the semiconductor device manufacturing process, it is required to achieve even higher wiring miniaturization, and polishing scratches that occur during polishing are becoming a problem.

Conventional cerium oxide slurries include particles having a size of 30 nm to 200 nm, and when polishing is performed, even when fine polishing scratches occur, when they are smaller than the conventional wiring width, there was no problem. However, this is a problem at present when further wiring miniaturization is continuously achieved. In response to this problem, attempts have been made to reduce the average particle diameter of cerium oxide particles, but in the case of conventional particles, when the average particle diameter is reduced, the mechanical action is reduced, and thus the polishing rate is reduced.

In this way, even when the polishing rate and polishing scratches are controlled by controlling the average particle diameter of the cerium oxide particles, it is very difficult to achieve the target level of polishing scratches while maintaining the polishing rate.

In addition, the conventional CMP slurry composition fails to present an optimized level of average particle diameter while optimizing the Ce³⁺ to Ce⁴⁺ ratio of the cerium oxide particles, and therefore, research is needed on a polishing slurry including cerium oxide particles that exhibit a high oxide film removal rate despite a small particle size by increasing the ratio of Ce³⁺ on the cerium oxide surface.

In addition, in the CMP process using the CMP slurry composition, the zeta potential may be adjusted in the pH range to expand the usability in the STI process, such as polishing a heterogeneous film by adjusting the zeta potential, increasing a nitride film polishing rate while implementing a polishing stop function in an oxide film, and so on. Therefore, research on a technology for adjusting the zeta potential by an additive is required.

As described above, the present inventors have developed cerium oxide particles having a size less than 10 nm, which are obtained through precipitation in a solution and have a greatly improved oxide film polishing rate, and through a combination of additive materials with the cerium oxide particles under such optimized conditions, they have developed a slurry composition that converts the zeta potential to a negative value under weakly acidic conditions, thereby completing the present invention.

### DETAILED DESCRIPTION OF THE INVENTION

### Technical Problem

The present invention has been derived to solve the above-mentioned problems, and one embodiment of the present invention provides a slurry composition for chemical mechanical polishing (CMP).

In addition, another embodiment of the present invention provides a method for manufacturing a semiconductor device.

The technical problems to be achieved by the present invention are not limited to the above-mentioned technical problems, and other technical problems that are not mentioned will be clearly understood by those skilled in the art to which the present invention pertains, from the description below.

### Technical Solution

As a technical means for solving the above-described technical problems, one aspect of the present invention provides:
a chemical mechanical polishing (CMP) slurry composition including: cerium oxide particles; a solvent; and a surface treatment agent, wherein the surface treatment agent converts a zeta potential of the cerium oxide particle surface to a negative value, and the average light transmittance in a wavelength range of 450 to 800 nm is 50% or more in an aqueous dispersion in which a content of the cerium oxide particles is adjusted to 1.0% by weight.

The cerium oxide particles have a zeta potential of 1 to 80 mV in a range of pH 2 to 8 before the surface treatment agent is added.

The cerium oxide particles have a zeta potential of −80 to −1 mV in a range of pH 7 to 10 after the surface treatment agent is added.

The content of the surface treatment agent may be 0.001% to 1% by weight based on the total weight of the CMP slurry composition.

The surface treatment agent may be at least one selected from hydroxyl ethylidene (1,1-diphosphonic acid) (HEDP), aminotrimethylenephosphonic acid (ATMP), 2-phosphonobutane 1,2,4-tricarboxylic acid (PBTC), ethylenediamine tetramethylene phosphonic acid (EDTMP), nitrilo-3-acetic acid, diethylenetriamine-5 acetic acid (DTPA), N-(2-hydroxyethyl)ethylenediamine-N,N′,N′-3-acetic acid (HEDTA), triethylenetetramine-6-acetic acid, 1,3-propanediamine-4-acetic acid, 1,3-diamino-2-propenol-N,N,N′, N′-4-acetic acid, N-(2-hydroxyethyl) imino-2-acetic acid, dihydroxy ethylglycine (DHEG), glycol ether diamine-4-acetic acid, propylenediamine tetraacetate (PDTA), ethylenediaminetetraacetate (EDTA), and salts thereof

The nitride film polishing inhibitor may be a sulfonic acid-based substance, a cationic surfactant, an amphoteric surfactant, or a combination thereof.

The surface treatment agent may be HEDP or EDTA.

The cerium oxide particles may be included in an amount of 0.001% to 5% by weight based on the total weight of the composition.

The CMP slurry composition may further include a pH adjuster, and the pH adjuster may be one or more inorganic acids selected from the group consisting of sulfuric acid, hydrochloric acid, nitric acid, and phosphoric acid, one or more organic acids selected from the group consisting of acetic acid, citric acid, glutaric acid, gluconic acid, formic acid, lactic acid, malic acid, malonic acid, maleic acid, oxalic acid, phthalic acid, succinic acid, and tartaric acid, one or more amino acids selected from the group consisting of lysine, glycine, alanine, arginine, valine, leucine, isoleucine, methionine, cysteine, proline, histidine, phenylalanine, serine, tricine, tyrosine, aspartic acid, tryptophan, and aminobutyric acid, imidazole, alkyl amines, alcohol amines, quaternary amine hydroxides, ammonia, or a combination thereof.

The composition may have a pH of 2 to 10.

The CMP slurry composition may have a silicon oxide film polishing rate of 1,000 to 5,000 Å/min.

The cerium oxide particles may have a secondary particle size measured by dynamic light scattering (DLS) particle size analyzer of 1 to 20 nm.

The cerium oxide particles may have a primary particle size measured by transmission electron microscopy (TEM) of 0.5 to 10 nm.

When analyzing by X-ray photoelectron spectroscopy (XPS), the sum of the XPS peak areas representing the Ce—O binding energy of Ce³⁺ may be 30% or more compared to the total sum of 100% of the XPS peak areas representing the Ce—O binding energy of the cerium oxide particle surface.

The cerium oxide particles may prepared by a step of obtaining a dispersion of particles by precipitating them at an acidic pH in a solution including a raw material precursor.

Another aspect of the present invention provides
a method of manufacturing a semiconductor device, the method including a step of polishing by using the chemical mechanical polishing slurry composition.

### Advantageous Effects

According to an embodiment of the present invention, the prepared cerium oxide particles can have a high oxide film removal rate even at a low content despite a small particle size when the particles are included in a chemical mechanical polishing (CMP) slurry by increasing the proportion of Ce³⁺ on the surface of the cerium oxide. In addition, by combining the surface treatment agent disclosed in the present invention, the zeta potential of the cerium oxide particle surface can be converted to a negative value, thereby expanding the application scope, such as nitride film polishing, and simultaneously obtaining an improved effect compared to cases where no additives are added.

In addition, according to one embodiment of the present invention, it is possible to provide cerium oxide particles and a slurry composition for CMP, which can minimize surface defects of a wafer and maximize a oxide film removal rate while minimizing surface defects, unlike the correlation between surface defects and oxide film removal rate, which was considered a trade-off relationship in the past.

The effects of the present invention are not limited to the above-described effects, and they should be understood as including all effects that may be inferred from the features of the invention described in the detailed description or claims of the present invention.

### DESCRIPTION OF THE DRAWINGS

FIG. 1 illustrates an oxide film removal mechanism according to one embodiment of the present invention.

FIGS. 2A to 2E show cross-sectional views illustrating a method of a semiconductor device according to one embodiment of the present invention, and FIGS. 2F and 2G illustrate a stepwise chemical mechanical polishing (CMP) process and a structure of a CMP facility according to another embodiment of the present invention.

FIG. 3 shows visually observed images of dispersions prepared by dispersing conventional cerium oxide particles and cerium oxide particles according to one embodiment of the present invention.

FIG. 4 shows transmission electron microscopy (TEM) images of the cerium oxide particles according to one embodiment of the present invention.

FIG. 5 shows scanning electron microscopy (SEM) and TEM images of conventional cerium oxide particles according to comparative examples.

FIG. 6 shows TEM images of conventional cerium oxide particles as comparative examples.

FIG. 7 shows the results of measuring the cerium oxide particles according to one embodiment of the present invention using a dynamic light scattering particle size analyzer (DLS). The analysis was performed using a Zetasizer Ultra from Malvern.

FIG. 8 shows the results of an X-ray diffraction (XRD) analysis of the cerium oxide particles according to one embodiment of the present invention.

FIG. 9 shows the results of an X-ray photoelectron spectroscopy (XPS) analysis of the cerium oxide particles according to one embodiment of the present invention and conventional cerium oxide particles having a size of 60 nm.

FIG. 10 shows the results of a Fourier transform infrared (FT-IR) spectroscopy analysis of powder made of cerium oxide particles prepared according to one embodiment of the present invention and powder made of conventional cerium hydroxide particles.

FIG. 11 shows the results of an FT-IR spectroscopy analysis of powder made of cerium oxide particles manufactured according to one embodiment of the present invention and powder made of particles formed under other conditions.

FIG. 12 shows the results of measuring the optical transmittance of slurries including cerium oxide particles according to one embodiment of the present invention and conventional cerium oxide particles of Comparative Examples 1 to 4, using ultraviolet-visible (UV-Vis) spectroscopy.

### BEST MODE

Hereinafter, the present invention will be described in more detail. However, the present invention may be implemented in various different forms, and the present invention is not limited to the embodiments described herein, but is defined only by the claims set forth below.

In addition, the terminology used in the present invention is used only to describe specific embodiments, and is not intended to limit the present invention. The singular expression includes the plural expression unless the context clearly indicates otherwise. Throughout the specification of the present invention, the term “comprising” a certain component does not exclude other components, but rather means that other components can be included, unless specifically stated otherwise.

The term “monodisperse” used in the present invention means that when cerium oxide particles are dispersed in a slurry, agglomeration into secondary particles is suppressed so that the particles relatively maintain the primary particle size. This may mean that the secondary particle size (D50) measured through dynamic light scattering (DLS) is 3.0 times or less, 2.8 times or less, 2.5 times or less, 2.2 times or less, 2.0 times or less, or advantageously 1.9 times or less, of the primary particle size through measured through by transmission electron microscopy (TEM). In addition, when examining particle size distribution, or the like, it does not exclude the inclusion of inevitable impurities of a relatively coarse size.

The term “transparent” used in the present invention means that when cerium oxide particles are dispersed in a slurry, the slurry composition is observed to be transparent when confirmed visually, and more specifically, it means that the average light transmittance for light in the visible light range is 50% or more, advantageously 70% or more, and even more advantageously 80% or more, and this may further mean that the cerium oxide particles of the present invention are suppressed from agglomerating into secondary particles and relatively maintain the primary particle size.

A polishing composition may be characterized according to its polishing rate (i.e., removal rate) and its planarization efficiency. The polishing rate refers to the rate at which a material is removed from the surface of a substrate, and is typically expressed in the unit of length (thickness) per unit time (e.g., angstroms (Å) per minute). Specifically, a polishing surface, for example, a polishing pad, must first contact with “high spots” of the surface and remove the material to form a planar surface. A process that achieves a planar surface with less removal of a material is considered more efficient than a process that requires more material to be removed to achieve planarity.

Often, the removal rate of a silicon oxide pattern may limit the rate of a dielectric polishing step in a shallow trench isolation (STI) process, and therefore, a high silicon oxide pattern removal rate is preferable to increase device throughput. However, when the blanket removal rate is too fast, over-polishing of the oxide in the exposed trenches may result in trench corrosion and increased device defects.

Hereinafter, the present invention will be described in detail.

A first aspect of the present invention provides
a CMP slurry composition including: oxide particles; a solvent; and a surface treatment agent, wherein wherein the surface treatment agent converts a zeta potential of the cerium oxide particle surface to a negative value, and the average light transmittance in a wavelength range of 450 to 800 nm is 50% or more in an aqueous dispersion in which a content of the cerium oxide particles is adjusted to 1.0% by weight.

Hereinafter, a CMP slurry composition according to the first aspect of the present invention will be described in detail.

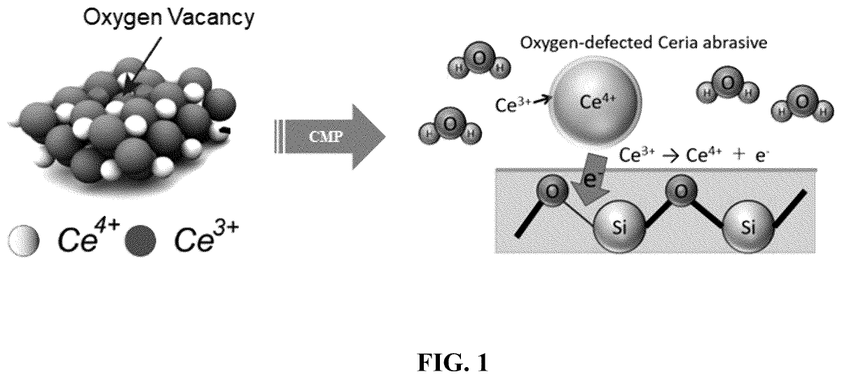

FIG. 1 illustrates an oxide film removal mechanism according to one embodiment of the present invention. As illustrated in FIG. 1, Ce³⁺ ions must be activated on the surface of cerium oxide particles to smoothly react with SiO₂.

In one embodiment of the present invention, when the surface treatment agent is included, there may be a stable dispersion effect at a basic pH. Since this is a major technical feature of the CMP slurry composition of the present invention compared to the conventional technology, it will be described in detail below. In particular, since this feature is a feature that exhibits a unique effect when combined with the unique cerium oxide particles of the present invention, which will be described in detail below, the feature will be described in detail below.

In one embodiment of the present invention, the surface treatment agent is capable of changing the surface zeta potential of the cerium oxide particles according to one embodiment of the present invention from a positive value to a negative value while maintaining the unique slurry properties of the cerium oxide particles.

As described below, the cerium oxide particles according to one embodiment of the present invention, which are obtained by a wet method at an acidic pH, are obtained in the form of a dispersion, and even when a solvent is added to the particles themselves to directly prepare a slurry, they may have a form in which ultrafine cerium oxide nanoparticles are monodispersed without a separate redispersion process, and the surface Ce³⁺ content is also maintained at a high level, so that the oxide film polishing rate is very high when a CMP slurry composition is prepared. It has been confirmed through research by the present inventors regarding the cerium oxide particles according to one embodiment of the present invention having the above-described unique characteristics that the performance intended in the conventional technology is not easily exhibited even when various additives used in the conventional technology are added. Furthermore, from the perspective of one of ordinary skill in the art using nanoparticles, for a composition including nanoparticles, it is necessary to find and combine materials suitable for specific nanoparticles to implement the desired characteristics or performance. The slurry composition according to one embodiment of the present invention may provide an optimal combination with an additive material that may change the zeta potential of the particles to a negative (−) value while maintaining the excellent oxide film polishing rate performance of the cerium oxide particles to a certain extent.

In one embodiment of the present invention, the content of the surface treatment agent may be 0.001% by weight or more, 0.002% by weight or more, 0.003% by weight or more, 0.004% by weight or more, or 0.005% by weight or more, and may be 1% by weight or less, 0.5% by weight or less, 0.1% by weight or less, 0.05% by weight or less, 0.03% by weight or less, or 0.01% by weight or less, based on the total weight of the CMP slurry composition. When the content of the surface treatment agent is less than 0.001% based on the total weight of the CMP slurry composition, the content is too small to sufficiently serve as a surface treatment agent, and thus the surface treatment agent may not exhibit the effect of improving the slurry stability. On the other hand, when the content exceeds 1%, the added surface treatment agent may interfere with the polishing process of cerium oxide, thereby reducing the oxide film polishing rate, or may become an impurity in the slurry composition.

In one embodiment of the present invention, the surface treatment agent may be at least one selected from hydroxyl ethylidene (1,1-diphosphonic acid) (HEDP), aminotrimethylenephosphonic acid (ATMP), 2-phosphonobutane 1,2,4-tricarboxylic acid (PBTC), ethylenediamine tetramethylene phosphonic acid (EDTMP), nitrilo-3-acetic acid, diethylenetriamine-5 acetic acid (DTPA), N-(2-hydroxyethyl)ethylenediamine-N,N′,N′-3-acetic acid (HEDTA), triethylenetetramine-6-acetic acid, 1,3-propanediamine-4-acetic acid, 1,3-diamino-2-propenol-N,N,N′,N′-4-acetic acid, N-(2-hydroxyethyl) imino-2-acetic acid, dihydroxy ethylglycine (DHEG), glycol ether diamine-4-acetic acid, propylenediamine tetraacetate (PDTA), ethylenediaminetetraacetate (EDTA), and salts thereof. Preferably, the surface treatment agent may be HEDP or EDTA.

Hereinafter, the details about the cerium oxide particles according to one embodiment of the present invention will be described. In one embodiment of the present invention, the CMP slurry composition uses cerium oxide particles having excellent dispersion stability, in particular, excellent polishing rate for a silicon oxide film.

In one embodiment of the present invention, the cerium oxide particles included as polishing particles in the slurry may have a positive zeta potential value before adding or inputting the surface treatment agent, and preferably, the zeta potential value may be 1 to 80 mV, 5 to 60 mV, or 10 to 50 mV in a range of pH 2 to 8. Since the zeta potential value of the cerium oxide particles has a positive value, the polarity of the silicon oxide film surface exhibits a negative value, and thus the polishing rate may be slightly reduced by the repulsive force between the cerium oxide particles and the surface of the silicon oxide film. The cerium oxide particles may have a zeta potential of −80 to −1 mV, −60 to −5 mV, or −50 to −10 mV in a range of pH 7 to 10 after the surface treatment agent is added. By surface-treating the cerium oxide particles so that the zeta potential value has a negative value, the nitride film polishing efficiency may be reduced.

In one embodiment of the present invention, the cerium oxide particles have lower hardness than silica particles or alumina particles, but the rate of polishing a surface containing silicon, such as a glass or semiconductor substrate, is very fast due to a chemical polishing mechanism in which a Si—O—Ce bond is formed between silica and cerium, so that the cerium oxide particles are advantageous for polishing a semiconductor substrate.

In one embodiment of the present invention, the particle size of the cerium oxide particles in the slurry may be measured by DLS analysis (secondary particles). The DLS analysis may be performed using analytical equipment known to those skilled in the art, and preferably, it may be performed using an Anton Parr particle size analyzer or a Malvern Zetasizer Ultra, but these are non-limiting examples, and the equipment is not limited thereto. The above-described secondary particles are formed in the slurry through agglomeration of the primary particles described below, and since the range where the attractive force acts increases as the surface area of the particles increases, it may be easily expected that agglomeration will occur well. In addition, as the pH range in the solution passes the isoelectric point, where the zeta potential of the particles becomes 0, agglomeration into secondary particles occurs. As disclosed in various conventional technologies, cerium oxide particles have an isoelectric point of approximately pH 7. In the case of a wet process, when particle synthesis is completed under basic conditions, the isoelectric point is inevitably passed while adjusting the pH for slurry production, and thus it may be difficult to achieve monodispersity within the slurry as the particles of one embodiment of the present invention.

In one embodiment of the present invention, the particle size of the cerium oxide particles measured by a DLS particle size analyzer may be 1 to 30 nm. In another embodiment of the present invention, the particle size may be 29 nm or less, 27 nm or less, 25 nm or less, 23 nm or less, 22 nm or less, 20.8 nm or less, 20.5 nm or less, 20.2 nm or less, 20 nm or less, 19.8 nm or less, 19.5 nm or less, 19.2 nm or less, 18 nm or less, 17 nm or less, or 15 nm or less, or may be 1.2 nm or more, 1.4 nm or more, 1.5 nm or more, 1.8 nm or more, 2 nm or more, 3 nm or more, or 4 nm or more. When the secondary particle size exceeds the above-described range, it means that a lot of agglomeration of primary particles occurs in the slurry composition, and in this case, it is difficult to consider it as a monodispersed slurry. When the secondary particle size is less than the above-described range, the polishing rate for the target film may be excessively inhibited, thereby lowering the polishing efficiency.

In one embodiment of the present invention, the particle size of the cerium oxide particles may be measured by a TEM (primary particles). In one embodiment of the present invention, the particle size of the cerium oxide particles measured by a TEM may be 11 nm or less. In another embodiment, the particle size may be 10.8 nm or less, 10.5 nm or less, 10.2 nm or less, 10 nm or less, 9.5 nm or less, 9.0 nm or less, 8.5 nm or less, 8.0 nm or less, 7.5 nm or less, 7.0 nm or less, 6.5 nm or less, 6.0 nm or less, 5.5 nm or less, 5.0 nm or less, 4.5 nm or less, or 4.0 nm or less, and may be 0.3 nm or more, 0.5 nm or more, 0.7 nm or more, 1.0 nm or more, 1.1 nm or more, 1.2 nm or more, 1.3 nm or more, 1.4 nm or more, 1.5 nm or more, 1.6 nm or more, 1.7 nm or more, 1.8 nm or more, 1.9 nm or more, 2.0 nm or more, 2.1 nm or more, 2.2 nm or more, 2.3 nm or more, or 2.4 nm or more. When the size of the cerium oxide particles is less than 0.3 nm, the crystallinity may be reduced, the polishing rate for the target film may be excessively inhibited, thereby reducing polishing efficiency. On the other hand, when it exceeds 11 nm, there is a concern that a large number of surface defects such as scratches may occur. In addition, in one embodiment of the present invention, the average particle size of the cerium oxide particles measured by a TEM may be 0.5 to 10 nm, preferably 1 to 10 nm, and more preferably 2 to 9 nm.

From the perspective of characterizing the cerium oxide particles according to one embodiment of the present invention, the cerium oxide particles may satisfy Mathematical Formula 1 below, where a is the size of the cerium oxide particles measured by a DLS particle size analyzer, and b is the size of the cerium oxide particles measured by a TEM.

a≤2.2b [Mathematical Formula 1]

This characteristic will be an indicator that the cerium oxide particles of the present invention have low agglomeration when dispersed in a slurry. When the coefficient b exceeds 2.2, it means that a lot of agglomeration occurs in the slurry, which indicates that the particle size becomes coarse, making it difficult to suppress wafer surface defects during polishing.

In one embodiment of the present invention, the particle size of the cerium oxide particles may be measured by an XRD analysis (primary particles). In one embodiment of the present invention, the particle size of the cerium oxide particles measured by an XRD analysis may be 11 nm or less. In another embodiment, the particle size may be 10.8 nm or less, 10.5 nm or less, 10.2 nm or less, 10 nm or less, 9.5 nm or less, 9.0 nm or less, 8.5 nm or less, 8.0 nm or less, 7.5 nm or less, 7.0 nm or less, 6.5 nm or less, 6.0 nm or less, 5.5 nm or less, 5.0 nm or less, 4.5 nm or less, or 4.0 nm or less, or may be 0.3 nm or more, 0.5 nm or more, 0.7 nm or more, 1.0 nm or more, 1.1 nm or more, 1.2 nm or more, 1.3 nm or more, 1.4 nm or more, 1.5 nm or more, 1.6 nm or more, 1.7 nm or more, 1.8 nm or more, 1.9 nm or more, 2.0 nm or more, 2.1 nm or more, 2.2 nm or more, 2.3 nm or more, or 2.4 nm or more. When the size of the cerium oxide particles is less than 0.3 nm, the crystallinity may be reduced, the polishing rate for the target film may be excessively inhibited, thereby reducing polishing efficiency. On the other hand, when it exceeds 11 nm, there is a concern that a large number of surface defects such as scratches may occur. In addition, in one embodiment of the present invention, the average particle size of the cerium oxide particles measured by an XRD analysis may be 0.5 to 10 nm, preferably 1 to 10 nm, and more preferably 2 to 9 nm.

In one embodiment of the present invention, the Ce³⁺ content on the surface of the cerium oxide particles may be analyzed using XPS, and for example, a theta probe base system manufactured by Thermo Fisher Scientific Co. may be used. The Ce³⁺ content on the surface of the cerium oxide polishing particles may be calculated by Chemical Formula 1 below.

Ce³⁺ content (%)=(Ce³⁺ peak area)/[(Ce³⁺ peak area)+(Ce⁴⁺ peak area)] [Chemical Formula 1]

In one embodiment, on the surface of the cerium oxide particle, when analyzed by XPS, XPS peaks representing Ce—O binding energy indicating Ce³⁺ may appear at 900.2 to 902.2 eV, 896.4 to 898.4 eV, 885.3 to 887.3 eV, and 880.1 to 882.1 eV. Specifically, on the surface of the cerium oxide particle, when analyzed by XPS, XPS peaks representing Ce—O binding energy indicating Ce³⁺ may appear at a first peak of 900.2 to 902.2 eV, a second peak of 896.4 to 898.4 eV, a third peak of 885.3 to 887.3 eV, and a fourth peak of 880.1 to 882.1 eV.

In one embodiment of the present invention, with respect to the total XPS peak area, the area of the first peak may be 3% or more, or 4% or more, the area of each of the second peak and the fourth peak may be 5% or more, 7% or more, or 10% or more, and the area of the third peak may be 4% or more, 5% or more, or 6% or more.

In addition, in one embodiment of the present invention, during an XPS analysis, a ratio of the sum of the XPS peak areas representing Ce—O binding energy indicating Ce³⁺ to the total sum of the XPS peak areas representing Ce—O binding energy on the surface of the cerium oxide particles may be 0.29 to 0.70. In another embodiment of the present invention, the ratio of the sum of the XPS peak areas representing Ce—O binding energy indicating Ce³⁺ to the total sum of the XPS peak areas representing Ce—O binding energy on the surface of the cerium oxide particles may be 0.18 or more, 0.19 or more, 0.192 or more, 0.195 or more, 0.198 or more, 0.20 or more, 0.202 or more, 0.205 or more, 0.208 or more, 0.21 or more, 0.22 or more, 0.24 or more, 0.25 or more, 0.27 or more, 0.28 or more, 0.30 or more, 0.32 or more, or 0.35 or more, and may be 0.90 or less, 0.88 or less, 0.85 or less, 0.83 or less, 0.80 or less, 0.77 or less, 0.75 or less, 0.72 or less, It may be 0.71 or less, 0.705 or less, 0.70 or less, 0.695 or less, 0.69 or less, 0.68 or less, 0.67 or less, 0.66 or less, 0.65 or less, 0.64 or less, 0.63 or less, 0.62 or less, 0.61 or less, or 0.60 or less. When the ratio is less than the above-described range, a sufficient amount of Ce³⁺ is not present on the surface of the cerium oxide particles, so it may be difficult to expect a sufficient increase in the oxide film polishing rate, and when it exceeds the above-described range, it may be difficult to interpret that the particles are present as cerium oxide particles when considering the oxidation number.

In other words, in one embodiment of the present invention, the surface of the cerium oxide particles for CMP may include Ce³⁺ in an amount of 18 atomic % or more, 19 atomic % or more, 20 atomic % or more, 22 atomic % or more, 24 atomic % or more, 25 atomic % or more, 27 atomic % or more, 28 atomic % or more, 30 atomic % or more, 32 atomic % or more, or 35 atomic % or more, and may include in an amount of Ce³⁺ in an amount of 90 atomic % or less, 88 atomic % or less, 85 atomic % or less, 83 atomic % or less, 80 atomic % or less, 77 atomic % or less, 75 atomic % or less, 72 atomic % or less, or 70 atomic % or less.

The cerium oxide particles according to one embodiment of the present invention have a high Ce³⁺ content on the particle surface. This is because the particle synthesis process in the liquid phase through a wet process according to one embodiment of the present invention is carried out under acidic conditions. Normally, cerium precursor materials containing trivalent cerium maintain the cerium trivalent state at an acidic pH, and in the preparation method according to one embodiment of the present invention, there is no conversion to a basic pH during the entire particle synthesis process, and therefore, the surface cerium trivalent content of the synthesized particles is high. This surface cerium trivalent content characteristic of the cerium oxide particles depends on whether surface defects are formed and maintained during the preparation process, and therefore, it may be considered as a characteristic independent of the technical characteristics such as the above-described primary particle size or secondary particle size. As described above, the cerium oxide particles according to one embodiment of the present invention have a high Ce³⁺ content on the particle surface, and when the surface Ce³⁺ content is relatively high, the oxide film polishing rate can be improved.

In one embodiment of the present invention, when FT-IR spectroscopy is performed on the powder formed of the cerium oxide particles, the infrared transmittance of the powder formed of the cerium oxide particles within a range of 3000 cm⁻¹ to 3600 cm⁻¹ in the spectrum specified by the FT-IR spectroscopy may be 90% or more, or 100% or less, 97% or less, or 95% or less. In addition, in one embodiment of the present invention, the infrared transmittance of the powder within a range of 720 cm⁻¹ to 770 cm⁻¹ may be 96% or less, and may be 85% or more, 88% or more, more preferably 90% or more, and even more preferably 92% or more. The fact that the infrared transmittance in the range of 3000 cm⁻¹ to 3600 cm⁻¹ of the FT-IR spectrum has a value within the above-described range may mean that the band due to the O—H group is relatively weak, which is different from the FT-IR spectrum of the powder formed of cerium hydroxide particles. In addition, the presence of the peak exhibiting the infrared transmittance in the range of 720 cm⁻¹ to 770 cm⁻¹ of the FT-IR spectrum of the powder formed of the cerium oxide particles according to one embodiment of the present invention may mean that Ce—O stretching occurs within the above-described range, which may mean that the particles prepared according to one embodiment of the present invention exhibit the characteristics of cerium oxide particles. In particular, in the wet method among the methods for preparing cerium oxide particles, when synthesized under basic conditions, a process for converting into cerium oxide, such as a separate heat treatment or exposure to oxygen for a long time, must be necessarily accompanied. Therefore, when an FT-IR spectrum is measured immediately after the particle synthesis process before such a post-process, peaks related to cerium hydroxide may be detected. On the other hand, since the cerium oxide particles according to one embodiment of the present invention are not formed by a process of first forming cerium hydroxide and then converting it into cerium oxide, only peaks related to cerium oxide may be detected even when measured immediately after synthesis.

In one embodiment of the present invention, the cerium oxide primary particle may be one or more selected from the group consisting of a spherical shape, a cube shape, a tetragonal shape, an orthorhombic shape, a rhombohedral shape, a monoclinic shape, a hexagonal shape, a triclinic shape, and a cuboctahedron shape, but preferably, the particle may have a spherical shape.

In one embodiment of the present invention, the cerium oxide particles may be prepared by a method of growing the particles through chemical synthesis, and preferably by a bottom-up method. As a method of synthesizing the cerium oxide particles, a sol-gel method, a supercritical reaction, a hydrothermal reaction, or a coprecipitation method may be used, but the method is not limited thereto. The above-described bottom-up method is a type of chemical synthesis that has recently been in the spotlight, and is a method of growing starting materials of atoms or molecules into nanometer-sized particles through chemical reactions.

In one embodiment of the present invention, the polishing composition includes wet cerium oxide particles. The wet cerium oxide particles may be any suitable wet cerium oxide particles. For example, the wet cerium oxide particles may be precipitated cerium oxide particles, including colloidal cerium oxide particles, or condensation-polymerized cerium oxide particles.

In one embodiment of the present invention, the wet cerium oxide particles also preferably have defects on the surface of the particles. Without wishing to be bound by any particular theory, pulverization of the cerium oxide particles may result in defects on the surface of the cerium oxide particles, and such defects may also affect the performance of the cerium oxide particles in the CMP composition. In particular, the cerium oxide particles may be crushed during pulverization, thereby exposing a less favorable surface state. This process, known as relaxation, causes atoms around the surface of the cerium oxide particle, having limited ability to reconstruct and limited ability to revert to a more favorable state, to form defects on the particle surface.

In one embodiment of the present invention, in the production of secondary particles of the polishing agent, each solvent has its own dielectric constant value, and the dielectric constant of the solvent changes the surface energy, surface charge, or the like in the nucleus generation and crystal growth during powder synthesis, thereby affecting the agglomeration and growth of the nucleus, which in turn affects the size and shape of the powder. The dielectric constant of the solvent and the surface potential (zeta potential) of the particles dispersed in the solvent are proportional to each other, and when the zeta potential is low, the surface repulsion between the fine particles or between the nuclei generated by the reaction is small, so that the agglomeration between the fine particles or between the nuclei may occur at a very fast rate in an unstable state. At this time, the magnitude of the surface repulsion is similar between the fine particles or the nuclei, so that agglomeration with a uniform size is possible. The secondary particles agglomerated in this way grow into relatively large-sized particles through a particle merging process such as a strong agglomeration reaction or Ostwald ripening of the primary fine particles or nuclei depending on the reaction conditions such as temperature and concentration.

When the cerium oxide is used as a polishing agent, the high reactivity of cerium oxide with silicon oxide causes a chemical bond of Si—O—Ce. Therefore, unlike a mechanical polishing that only removes a hydrated layer formed on the surface, cerium oxide polishes the silicon oxide film by removing silicon oxide lumps from the surface of the silicon oxide film as if peeling them off. In addition, the cerium oxide powder according to the embodiment of the present invention has a low strength due to its small particle size, so that it has an advantage in that it has excellent wide-area planarity during polishing and at the same time, it can also solve the problem of micro scratches formed by coarse particles.

Hereinafter, a CMP slurry composition including the cerium oxide particles and the surface treatment agent according to one embodiment of the present invention will be described.

In one embodiment of the present invention, in one embodiment, in the aqueous dispersion in which the content of the cerium oxide particles is adjusted to 1.0% by weight, the average light transmittance for light having a wavelength of 450 to 800 nm may be 50% or more, or 60% or more, and preferably the average light transmittance may be 70% or more, more preferably 80% or more, and even more preferably 90% or more. In addition, in another embodiment of the present invention, the light transmittance of the aqueous dispersion for light having a wavelength of 500 nm may be 50% or more, 55% or more, 60% or more, 65% or more, 70% or more, 75% or more, or 80% or more. In addition, the light transmittance of the aqueous dispersion for light having a wavelength of 600 nm may be 75% or more, 80% or more, 85% or more, or 90% or more. In addition, the light transmittance for light having a wavelength of 700 nm may be 87% or more, 90% or more, 93% or more, or 95% or more. The fact that the light transmittance value of the slurry composition satisfies the above-described range may mean that the primary particle size of the cerium oxide particles according to one embodiment of the present invention is small, and further, the agglomeration into secondary particles is less compared to conventional ceria particles. When the agglomeration is little, the dispersion stability is high so that the particles can be uniformly distributed, and since the number of particles in contact with the wafer increases, the oxide film polishing rate can be excellent, and since the particles themselves are fine, it can be easily estimated that when the target film is polished using the slurry composition including the particles, the probability of generating defects such as scratches occurring on the surface will be reduced. In other words, in the case of cerium oxide particles having a size of 10 nm or less based on the primary particles, it may be predicted that the higher the light transmittance in the visible light region, the better the silicon oxide film polishing rate. In addition, the light transmittance is a characteristic that can be maintained even when the surface treatment agent, which is an additive, is further included.

In one embodiment of the present invention, the cerium oxide particles may be included in an amount of 5% by weight or less based on the total weight of the slurry composition for CMP. In another embodiment of the present invention, the cerium oxide particles may be included in an amount of 4% by weight or less, 3% by weight or less, 2% by weight or less, 1.5% by weight or less, 1% by weight or less, 0.8% by weight or less, 0.5% by weight or less, 0.4% by weight or less, 0.3% by weight or less, 0.2% by weight or less, less than 0.2% by weight, 0.19% by weight or less, 0.15% by weight or less, 0.12% by weight or less, 0.10% by weight or less, 0.09% by weight or less, or 0.07% by weight or less, and may be 0.0001% by weight or more, or 0.001% by weight or more based on the total weight of the slurry composition for CMP. The CMP slurry composition of the present invention can achieve a high oxide film polishing efficiency despite using a slurry having the same polishing rate, even when the cerium oxide particles are added in a smaller amount based on the total weight of the CMP slurry composition.

In one embodiment of the present invention, the pH of the composition may be 2 to 10. In one embodiment of the present invention, the CMP slurry composition may include one or more acidic or basic pH adjusters and buffers capable of controlling the pH in consideration of the final pH, polishing rate, polishing selectivity, and the like of the composition. As the pH adjuster for controlling the pH, a pH adjuster capable of controlling the pH without affecting the characteristics of the CMP slurry composition may be used. In one embodiment of the present invention, the pH adjuster may be an acidic pH adjuster or a basic pH adjuster to achieve an appropriate pH.

In one embodiment of the present invention, examples of the pH adjuster may include one of more inorganic acids selected from the group consisting of sulfuric acid, hydrochloric acid, nitric acid, and phosphoric acid, one of more organic acids selected from the group consisting of acetic acid, citric acid, glutaric acid, gluconic acid, formic acid, lactic acid, malic acid, malonic acid, maleic acid, oxalic acid, phthalic acid, succinic acid, and tartaric acid, one or more amino acids selected from the group consisting of lysine, glycine, alanine, arginine, valine, leucine, isoleucine, methionine, cysteine, proline, histidine, phenylalanine, serine, tricine, tyrosine, aspartic acid, tryptophan, and aminobutyric acid, imidazole, alkyl amines, alcohol amines, quaternary amine hydroxides, ammonia, or a combination thereof. In particular, the pH adjuster may be triethanolamine, tetramethylammonium hydroxide (TMAH or TMAOH), or tetraethylammonium hydroxide (TEAH or TEA-OH). In addition, examples of the pH adjuster may include at least one selected from the group consisting of ammonium methyl propanol (AMP), tetra methyl ammonium hydroxide (TMAH), potassium hydroxide, sodium hydroxide, magnesium hydroxide, rubidium hydroxide, cesium hydroxide, sodium bicarbonate, sodium carbonate, triethanolamine, tromethamine, and niacinamide. Preferably, the pH adjuster may be triethanolamine or aminobutyric acid.

In one embodiment of the present invention, any solvent used in a CMP slurry composition may be used, and for example, deionized water may be used, but the present invention is not limited thereto. In addition, ultrapure water may be preferably used. The content of the solvent may be the remaining content excluding the content of the cerium oxide particles and other additional additives based on the total CMP slurry composition. In one embodiment of the present invention, the solvent may include water (e.g., deionized water) as an aqueous carrier, and may include one or more water-miscible organic solvents. Examples of organic solvents that may be used may include: alcohols such as propenyl alcohol, isopropyl alcohol, ethanol, 1-propanol, methanol, 1-hexanol, and the like; aldehydes such as acetaldehyde, and the like; ketones, such as acetone, diacetone alcohol, methyl ethyl ketone, and the like; esters such as ethyl formate, propyl formate, ethyl acetate, methyl acetate, methyl lactate, butyl lactate, ethyl lactate, and the like; sulfoxides such as such as dimethyl sulfoxide (DMSO); ethers such as tetrahydrofuran, dioxane, diglyme, and the like; amides such as N,N-dimethylformamide, dimethylimidazolidinone, N-methylpyrrolidone, and the like; polyhydric alcohols and their derivatives, such as ethylene glycol, glycerol, diethylene glycol, diethylene glycol monomethyl ether, and the like; and nitrogen-containing organic compounds such as acetonitrile, amylamine, isopropylamine, dimethylamine, and the like.

In one embodiment of the present invention, the polishing composition optionally further includes one or more other additives. The polishing composition may include a surfactant and/or a rheology modifier, including a viscosity enhancing agent and a coagulant (e.g., a polymeric rheology modifier such as a urethane polymer), a biocide (e.g., KATHON™ LX), and the like. Suitable surfactants include, for example, cationic surfactants, anionic surfactants, anionic polyelectrolytes, nonionic surfactants, amphoteric surfactants, fluorinated surfactants, and mixtures thereof.

In one embodiment of the present invention, the CMP slurry composition has excellent dispersion stability and, in particular, a high polishing rate for a silicon oxide film.

In one embodiment of the present invention, the CNP slurry composition may have a silicon oxide film polishing rate of 10 Å/min, preferably 1,000 Å/min or more, more preferably 2,000 Å/min or more. In particular, in the case of the CMP slurry composition using cerium oxide particles according to one embodiment of the present invention, the particle size is small even in a low content range of cerium oxide particles, so the number of particles included is greater than that of a slurry composition including conventional cerium oxide particles, and since the Si—O—Ce bond increases due to the high surface Ce³⁺ content, the silicon oxide film polishing rate may be significantly increased.

A second aspect of the present invention provides
a method of manufacturing a semiconductor device, the method including a step of polishing by using the CMP slurry composition.

Although detailed descriptions of parts that overlap with the first aspect of the present invention have been omitted, the contents described for the first aspect of the present invention may be equally applied even when the description is omitted for the second aspect.

Hereinafter, a method of manufacturing a semiconductor device according to the second aspect of the present invention will be described in detail.

First, regarding the shallow trench isolation (STI) routine process, among the processes for planarizing the insulating film, photolithography, etching, and polishing may be considered as basic processes that are commonly applied.

The STI process may begin with a photolithography process, which is a first step to isolate devices. The photolithography process is performed with auxiliary equipment called a track and with an exposure device that exposes light to copy the circuit pattern (mask) onto a wafer. First, a photoresist is applied. Since the photoresist has a high viscosity, it is applied thinly on an insulating film while rotating the wafer. The applied photoresist must have a uniform height to ensure an appropriate exposure depth. When the photoresist depth is not sufficient during exposure, photoresist residue will remain during development, and the lower film (insulating layer) is not properly removed during a subsequent etching process. After exposure, the wafer is moved back to the track equipment, and a development process is performed to remove the photosensitive area.

As a second step, etching of STI is a process of removing the insulating layer (oxide layer+nitride layer) and part of the substrate immediately below the developed area (where the photosensitive film is removed). The etching process may be a dry or wet process. The dry etching method is usually a method of digging down using a plasma state. Compared to the wet (liquid) method, the dry method may be advantageous in establishing the trench shape by digging downward only without etching side walls (anisotropic etching). In this case, over-etching may occur, so it will be necessary to perform etching after accurately calculating the etching endpoint. Since residues remain after etching, they may be dealt with.

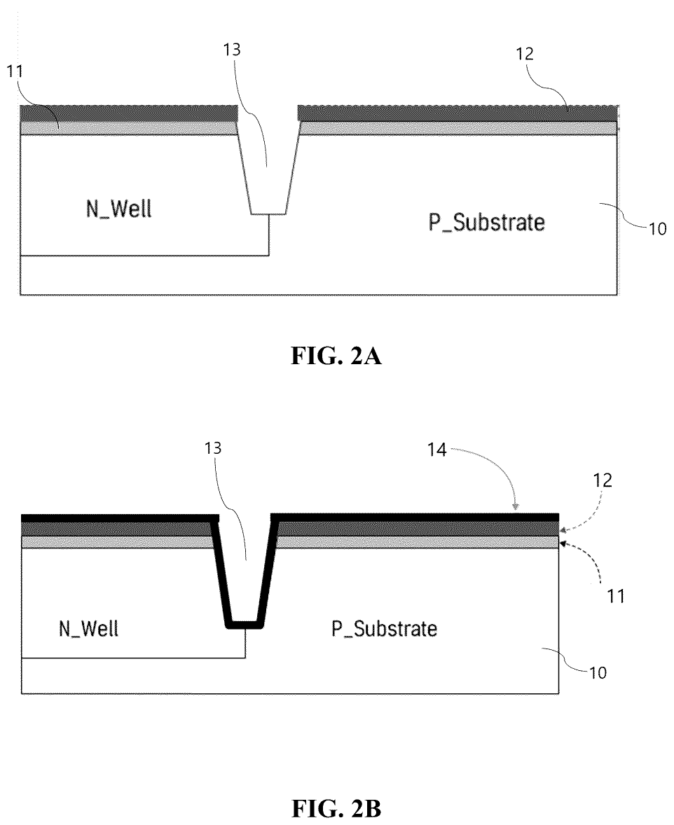

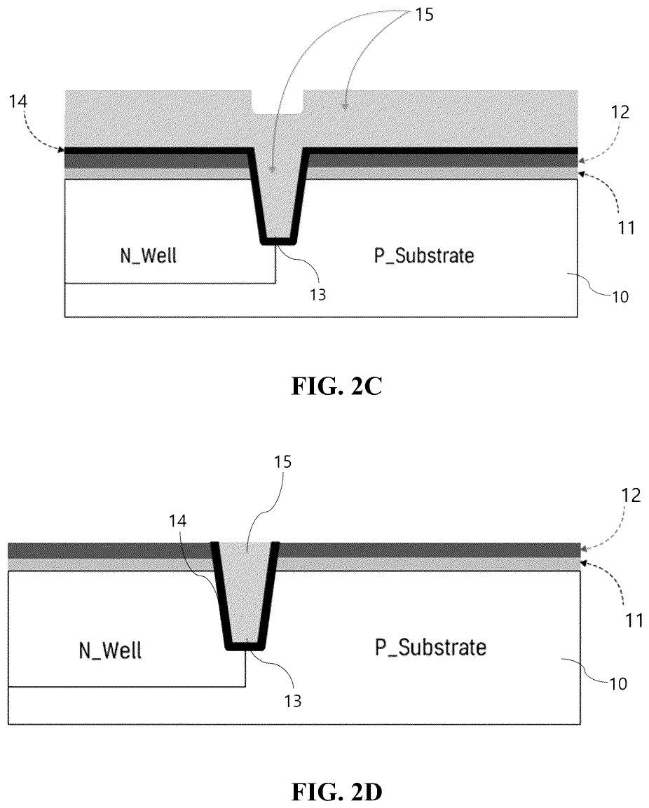

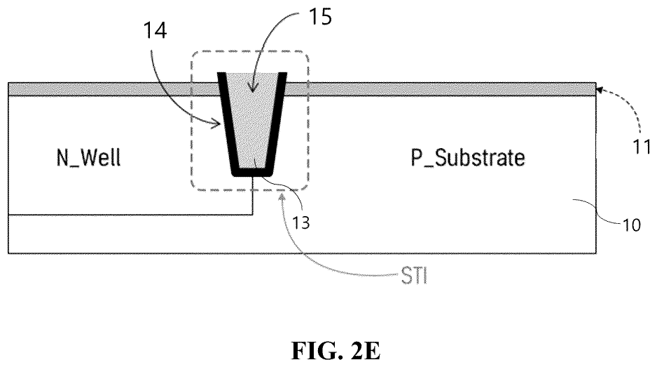

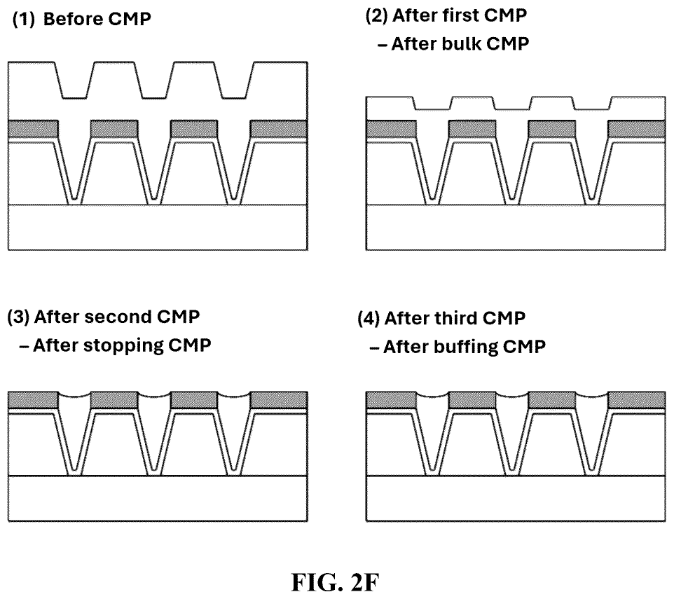

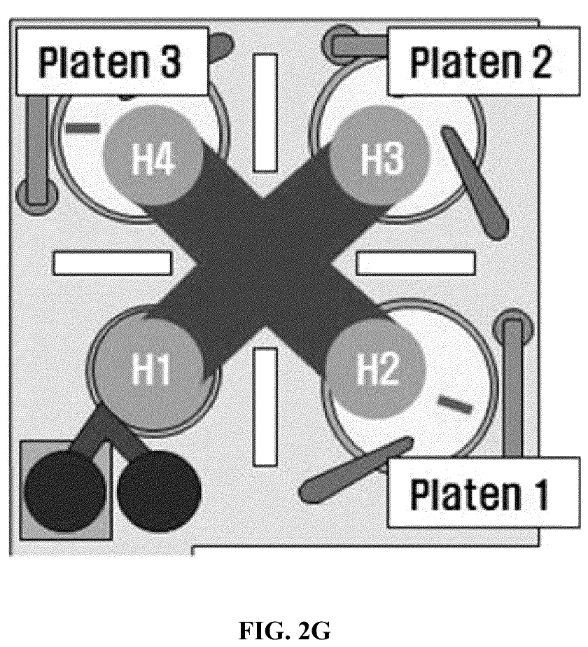

After etching the shape of the trench, the photoresist layer is no longer useful, so it may be removed through ashing. The ashing may be preferably performed using plasma, enabling more accurate ashing. The shape of the semiconductor device that has undergone the ashing process is illustrated in FIG. 2A.

A method of manufacturing a semiconductor device according to an embodiment of the present invention may include a step of simultaneously polishing a silicon oxide film, a silicon nitride film, and a polysilicon film using the CMP slurry composition.

FIGS. 2A to 2E show cross-sectional views illustrating a method of manufacturing a semiconductor device according to an embodiment of the present invention.

Referring to FIG. 2A, a trench 13 may be formed in an upper film 11 on a lower film 10. For example, the upper film 11 may be formed on the lower film 10, and a nitride film 12 (polishing stop film) may be formed on the upper film 11. The lower film 10 may include a film formed of any materials. For example, the lower film 10 may be an insulating film, a conductive film, a semiconductor film, or a semiconductor wafer (substrate). The upper film 11 may include an insulating film (oxide film), a conductive film, a semiconductor film, or a combination thereof.

When the upper film 11 includes a plurality of laminated insulating films, the insulating films may be of the same type or different types. For example, the upper film 11 may include silicon oxide films and silicon nitride films that are alternately and repeatedly laminated. The upper film 11 may further include a semiconductor film and a lower insulating film under the silicon oxide films and silicon nitride films. For example, the lower insulating film may be disposed under the semiconductor film.

The nitride film 12 (polishing stop film) may be formed to have a relatively large thickness (e.g., 100 Å to 4,000 Å) by depositing, for example, silicon nitride (e.g., SiN), polysilicon, metal nitride (for example, TiN), metal, and the like. The trench 13 may be formed by an etching process or a drilling process. The trench 13 may have a depth that may penetrate the nitride film 12 (polishing stop film) and the upper film 11 to reach the lower film 10. For example, the trench 13 may have a sufficient depth to expose the lower film 10.

Referring to FIG. 2B, a double oxide film may be formed in STI. First, before filling the trench 13 having a secured space with an insulating material, a liner oxide film is thinly applied as a first insulating film 14 by a diffusion method so that the second insulating film is well formed on the silicon substrate using chemical vapor deposition (CVD) in the subsequent step. According to another embodiment of the present invention, when filling the trench 13 by high-density plasma CVD (HDPCVD), the liner oxide film may also serve to prevent damage from high-energy plasma. According to one embodiment of the present invention, the first insulating film (liner oxide film) may be formed as a thin film such as a gate oxide film by injecting oxygen gas into a furnace for diffusion and heating the same to a high temperature. In addition, according to another embodiment of the present invention, a nitride film may be used instead of an oxide film.

Referring to FIG. 2C, a first insulating film 14 and a second insulating film 15 may be formed by depositing a plurality of insulating materials to fill the trench 13. The first insulating film 14 and the second insulating film 15 may have different densities and deposition rates. According to embodiments of the present invention, the first insulating film 14 may be formed by depositing a high-density insulating material, and the second insulating film 15 may be formed by depositing a low-density insulating material. For example, the first insulating film 14 may be formed by depositing and patterning a high-density plasma (HDP) oxide. The first insulating film 14 may be formed in a shape extending along an inner surface of the trench 13. For example, the first insulating film 14 may have a U-shape or a pipe shape that is opened upward.

Since the first insulating film 14 has a high density, it is difficult for voids to occur within the first insulating film 14, and accordingly, cracks originating from the voids may be eliminated or significantly reduced when a subsequent heat treatment process is performed. The second insulating film 15 may be formed by depositing, for example, tetraethylorthosilicate (TEOS) oxide to a thickness sufficient to cover the polishing stop film 12 while filling the trench 13 in which the first insulating film 14 is formed. The second insulating film 15 may be formed at a faster deposition rate than the first insulating film 14. Due to the fast deposition rate of the second insulating film 15, the trench 13 may be filled with the second insulating film 15 relatively quickly.

According to another embodiment of the present invention, although not shown, the second insulating film 15 may be partially removed so that the second insulating film 15 remains on the trench 13. For example, the second insulating film 15 may be selectively removed to limit or open a specific area, such as a cell memory area of a semiconductor device, by a photolithography process and an etching process. Accordingly, part or all of the second insulating film 15 on the polishing stop film 12 may be removed, and the second insulating film 15 may remain on the trench 13. The opening process of the specific area may be performed optionally and may not necessarily be performed.

Referring to FIG. 2D, a planarization process for the second insulating film 15 may be performed. For example, the second insulating film 15 may be planarized by a CMP process. The CMP process may be continuously performed until the nitride film 12 (polishing stop film) is exposed. The CMP process may be performed after the formation of the second insulating film 15 of FIG. 2B. In this case, since the surface of the nitride film 12 (polishing stop film) is relatively flat, or even when it is not flat, its unevenness is not severe, the CMP process may be easily performed.

Thereafter, referring to FIG. 2E, a nitride film may be removed to form an STI. The nitride film is intended to protect the upper film 11 from being affected by the first insulating film 14. The upper film 11 may be a gate oxide film that must be thin and reliable, so it must be handled carefully. When removing the nitride film by an etching method (wet), the wafer may be immersed in a chemical solution so that only the nitride film is etched without etching the oxide film. For this purpose, a solution having a high selectivity (etching ratio) for the nitride film may be used. In another embodiment of the present invention, the nitride film may also be removed by CMP. In this case, it may not be necessary to etch the nitride film, but since there is a possibility of physically damaging the oxide film, the nitride film is preferably treated chemically by an etching method in order to protect the oxide film.

According to another embodiment of the present invention, the CMP process may completely remove the first insulating film 14 and the second insulating film 15 on the nitride film 12 (polishing stop film) after the gap filling in order to isolate the active area and the field area. The process may be largely divided into three steps, as shown in FIG. 2F.

In the first step, local planarization is achieved while performing bulk CMP on the second insulating film 15 on the platen. In the second step, the second insulating film 15 whose level difference is alleviated on the platen is cleaned or polished, and the polishing is stopped when the nitride film 12 (polishing stop film) is exposed. At this time, polishing end point detection (EPD) is used to detect the point at which the heterogeneous film is exposed. In the third step, the second insulating film 15 residue that may remain on the nitride film 12 (polishing stop film) on the platen may be removed, and the nitride film and oxide film may be polished for targeting.

FIG. 2G shows the structure of a CMP facility according to one embodiment of the present invention. This facility consists of three platens, and as described above, STI CMP polishing may be performed stepwise by sequentially going through platens 1, 2, and 3. After polishing, it moves to a cleaning section, and cleaning is performed to complete the process.

In addition, the method of manufacturing a semiconductor device according to one embodiment of the present invention may use any polishing method of simultaneously polishing a silicon oxide film, a silicon nitride film, and a polysilicon film using the CMP slurry composition, as long as the polishing methods and conditions are those that are commonly used conventionally, without limitation, and the method is not specifically limited in the present invention.

The CMP slurry composition according to one embodiment of the present invention has high dispersion stability and a high Ce³⁺ content on the surface of the cerium oxide particles included in the slurry composition, thereby increasing the polishing rate on a silicon-containing substrate by a chemical polishing mechanism that forms Si—O—Ce between silica and cerium. Therefore, the CMP slurry composition can be effectively used to remove especially a silicon oxide film from the surface of a semiconductor device in a CMP process even under conditions including a low ceria content.

A third aspect of the present invention provides
a semiconductor device including: a substrate; and a trench filled with an insulating material on the substrate, wherein the trench is formed by polishing at least one film selected from the group consisting of a silicon oxide film, a silicon nitride film, and a polysilicon film, using a CMP slurry composition, and the CMP slurry composition includes: cerium oxide particles; a solvent; and a surface treatment agent.

Although detailed descriptions of parts that overlap with the first aspect and the second aspect of the present invention have been omitted, the contents described for the first aspect and the second aspect of the present invention may be equally applied even when the description is omitted for the third aspect.

A fourth aspect of the present invention provides
a method of preparing cerium oxide particles, including: a step of preparing a raw material precursor; and
a step of pulverizing or precipitating cerium oxide particles in a solution including the raw material precursor to obtain a dispersion of cerium oxide particles for CMP.

Although detailed descriptions of parts that overlap with the first aspect to the third aspect of the present invention have been omitted, the contents described for the first aspect to the third aspect of the present invention may be equally applied even when the description is omitted for the fourth aspect.

In one embodiment of the present invention, a step of preparing a raw material precursor may be included. As the raw material precursor, any precursor material capable of producing cerium oxide particles as a product may be used without limitation.

In one embodiment of the present invention, a step of pulverizing or precipitating cerium oxide particles in a solution including the raw material precursor to obtain a dispersion of cerium oxide particles for CMP may be included. The step of pulverizing cerium oxide particles in a solution including the raw material precursor may be, for example, pulverization through a milling process, and the pulverization method may be determined without limitation within the scope of common technical knowledge of a person skilled in the art. The step of precipitating cerium oxide particles in a solution including the raw material precursor to obtain a dispersion of cerium oxide particles may further include a step of removing a supernatant, a step of filtering, or the like.

In particular, in the embodiment of the present invention, the entire particle synthesis process may be performed at room temperature and without going through an alkaline pH, and therefore, an energy-efficient manufacturing process can be implemented while exhibiting the above-described particle characteristics.

Hereinafter, examples of the present invention will be described in detail so that those with ordinary knowledge in the technical field to which the present invention pertains may easily implement the present invention. However, the present invention may be implemented in various different forms and is not limited to the examples described herein.

### Preparation Example 1. Preparation of Oxide Cerium Particles

The cerium oxide particles according to one embodiment of the present invention may be synthesized through chemical synthesis in a bottom-up manner. In the embodiment of the present invention, the cerium oxide particles were prepared by one method selected from among the methods for preparing cerium oxide particles described below.

According to one embodiment of the manufacturing method of the present invention, first, about 2 to 4 kg of cerium nitrate was added to a sufficient amount of deionized water and stirred. Nitric acid was added to the precursor solution to adjust the pH to 1.0 or lower. Ammonia water was added to the prepared mixture and stirred until a precipitate was formed. The pH of the stirred mixture indicated that the mixture was strongly acidic (2 or lower), and it was confirmed that the product rapidly precipitated when the product was allowed to stand after stirring was completed. After removing the supernatant excluding the precipitate, a certain amount of deionized water was added, and a pale yellow cerium oxide particle dispersion was generated. The prepared dispersion was circulated and filtered through a membrane filter to obtain a transparent yellow cerium oxide dispersion.

According to a preparation method according to another embodiment of the present invention, first, 150 g of cerium oxide or cerium hydroxide was dispersed in 3 kg of deionized water and stirred to an extent that the particles did not precipitate. Nitric acid was added to the mixture until the pH became 1.0 or lower. The mixture was added to a milling machine filled with 0.05 mm zirconia beads and pulverized while circulating at 4,000 rpm. As the milling progressed, it was observed that the white opaque cerium oxide dispersion gradually changed into a yellow transparent cerium oxide dispersion. After the milling was completed, the prepared yellow transparent cerium oxide dispersion was precipitated and then circulated and filtered through a membrane filter to obtain a pure yellow transparent cerium oxide dispersion.

According to a preparation method according to still another embodiment of the present invention, first, about 2 to 4 kg of ceric ammonium nitrate was added to a sufficient amount of ethanol and stirred. A basic imidazole solution was added and stirred until a precipitate was formed in the precursor solution. The pH of the stirred mixture indicated that the mixture was strongly acidic (2 or less), and it was confirmed that the product was rapidly precipitated when the product was allowed to stand after stirring was completed. After removing the supernatant excluding the precipitate, a certain amount of deionized water was added, and a dispersion of cerium oxide particles was produced. The prepared dispersion was circulated and filtered through a membrane filter to obtain a transparent dispersion of cerium oxide.

According to a preparation method according to yet another embodiment of the present invention, first, 1.1 kg of cerium nitrate and 10 kg of deionized water were mixed in a reaction vessel to prepare a strongly acidic solution. The stirring speed of the reaction vessel was maintained at 200 rpm, and the temperature was maintained at room temperature. A 1:1 mixed solution of a 25% ammonia solution and deionized water was prepared and added to the reaction vessel until the pH became 7.0. After stirring for one hour, a 1:1 mixed solution of 70% nitric acid and deionized water was added until the pH became 1.0. The reactor temperature was increased to 100° C., and the reaction was performed for four hours. During the reaction, purple coarse particles were dissociated to produce yellow transparent cerium oxide nanoparticles. The obtained particles were circulated and filtered using a membrane filter to remove impurities and obtain a pure cerium oxide nanoparticle dispersion.

### Preparation Example 2. Preparation of Chemical Mechanical Polishing (CMP) Slurry Including Cerium Oxide Particles

The cerium oxide particles prepared in Preparation Example 1 were added to deionized water, the polishing agent concentration was adjusted to 0.05% by weight, and triethanolamine was added to adjust the pH to 5.5, 8.0, 9.0, and 10.0 to prepare a CMP slurries (2-1, 2-2, 2-3, and 2-4).

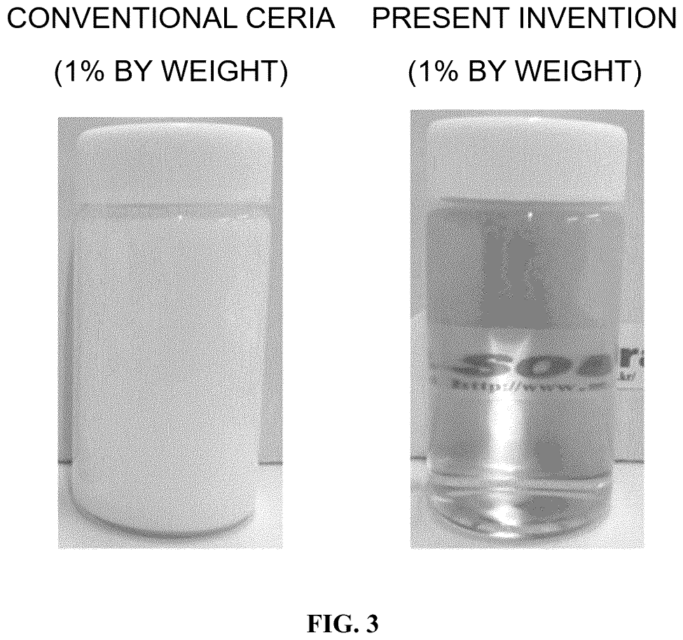

According to FIG. 3, in the case of the slurry including the conventional ceria particles, it was even visually observed that the turbidity was high, whereas in the case of the slurry including the cerium oxide particles of the present invention, it was observed that the slurry was transparent, so it could be estimated that the slurry had monodispersity.

### Preparation Example 3. Preparation of CMP Slurry Including Surface Treatment Agent

The cerium oxide particles prepared in Preparation Example 1 were added to deionized water, the polishing agent concentration was adjusted to 0.05% by weight, 0.1% of HEDP as a surface treatment agent was added, and sufficient stirring was performed. After stirring, triethanolamine was added to adjust the pH to 5.5, 8.0, 9.0, and 10.0, respectively, to prepare CMP slurries (3-1, 3-2, 3-3, and 3-4).

### Experimental Example 1. Scanning Electron Microscopy (SEM) and TEM Analysis of Cerium Oxide Particles

According to one embodiment of the present invention, the dispersion of Preparation Example 1 was dried at approximately 80 to 90° C. to prepare powder-form cerium oxide particles (primary particles) (Sample A). Meanwhile, the cerium oxide particles used in the preparation of the dispersions of Comparative Examples 1 to 10 were each prepared (Samples B1, B2, B3, and B4 in the order). Images were taken of each of the prepared samples using a TEM measurement device.

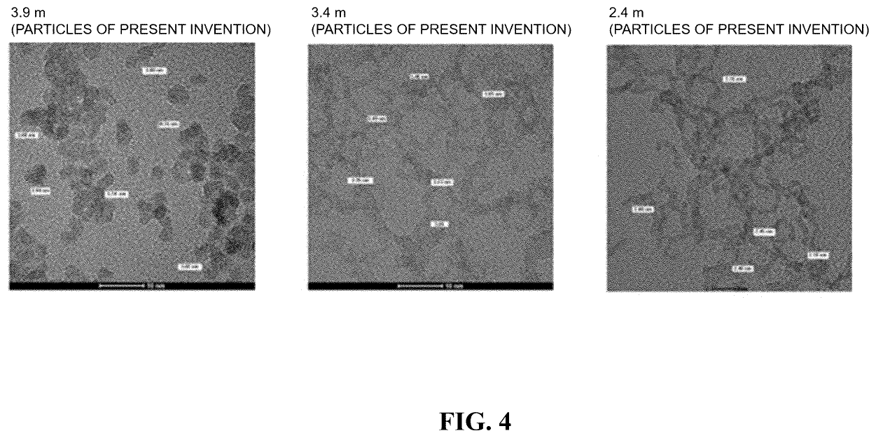

FIG. 4 shows TEM images of the cerium oxide particles according to one embodiment of the present invention.

Referring to FIG. 4, it could be confirmed that the average particle size of the cerium oxide particles prepared according to one embodiment of the invention according to the TEM measurement was about 4 nm or less (3.9 nm, 3.4 nm, and 2.9 nm, respectively, in repeated measurements). It can be seen that the average primary particle size of the cerium oxide particles according to one embodiment of the present invention was 4 nm or less. In addition, it can be confirmed that the cerium oxide particles generally have a spherical particle shape. Spherical cerium oxide particles having a small particle size and a relatively uniform size distribution may have a large specific surface area and excellent dispersion stability and storage stability.

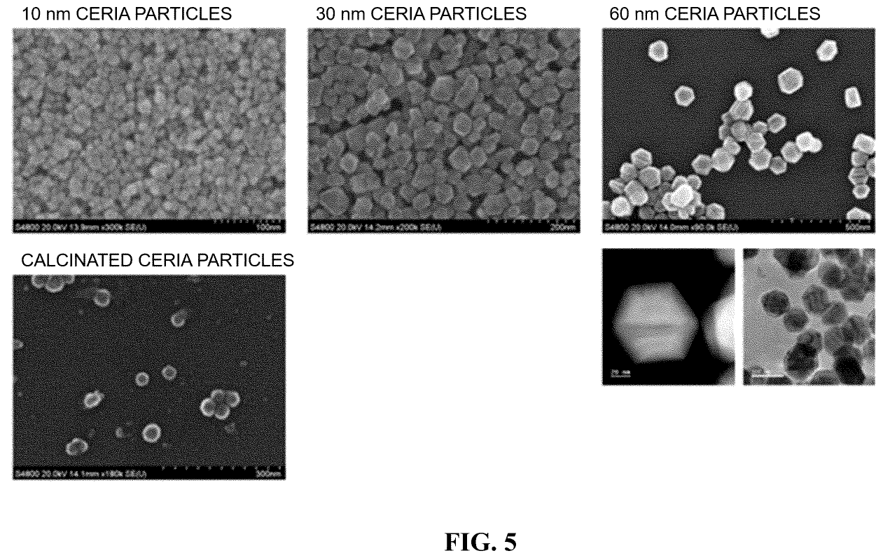

FIG. 5 shows SEM and TEM images of conventional cerium oxide particles according to comparative examples.

Referring to FIG. 5, it can be seen that the commercially available conventional cerium oxide particles exhibited particle sizes suitable for each size class, and the particles separately prepared by a calcination method all exhibited a primary particle size of more than 10 nm on average. When the results are compared with the cerium oxide particles according to an embodiment of the present invention shown in FIG. 4, which had an average particle size of 4 nm or less measured by TEM, it can be confirmed that the conventional cerium oxide particles and the cerium oxide particles prepared by a common calcination method have much larger particle sizes. On the other hand, it was confirmed that the cerium oxide particles of the present invention are formed to have a small particle size (primary particle) itself, and it can be expected that the smaller the cerium oxide particle size, the more defects such as scratches on the surface of the polishing target film can be reduced.

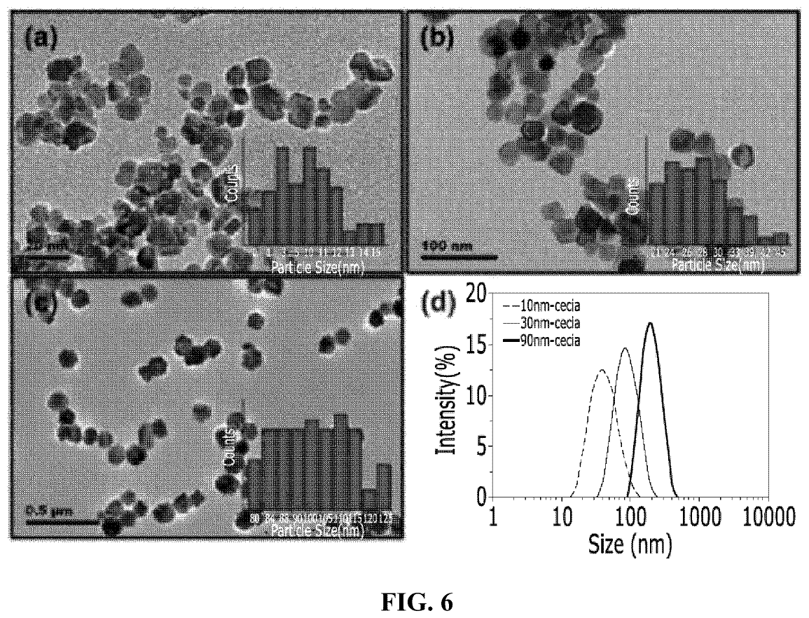

In addition, FIG. 6 shows TEM images of conventional cerium oxide particles as a comparative example. Referring to FIG. 6, it can be confirmed that the conventional cerium oxide particles having a particle size less than or equal to 10 nm included particles having edges and particles having a spherical shape, and the conventional cerium oxide particle having a particle size of 30 nm or more is composed of angular particles having edges. On the other hand, as described above, the cerium oxide particles according to the embodiment of the present invention generally have a spherical shape, and as the cerium oxide particles of the present invention have such a spherical particle shape and a fine particle size, a large number of particles may be included, and therefore, when polishing a silicon oxide film, the probability of surface defect occurrence can be reduced and the wide-area planarity can be increased.

### Experimental Example 2. DLS Analysis of Cerium Oxide Particles

The slurry composition of Preparation Example 2 according to one embodiment of the present invention and the slurry compositions of Comparative Examples 1, 2, 3 and 4 were prepared as samples. For each of the prepared samples, analysis was performed using DLS equipment.

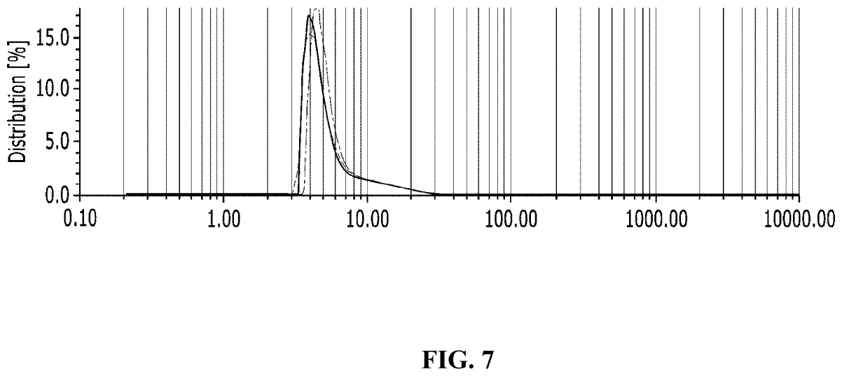

FIG. 7 shows the result of dynamic light scattering (DLS) analysis (Malvern Zetasizer Ultra) of cerium oxide particles according to one embodiment of the present invention. In addition, Table 1 below shows the D50 values obtained by DLS analysis of cerium oxide particles according to one embodiment of the present invention and cerium oxide particles of Comparative Examples.

TABLE 1

| | D50 |
|---|---|
| | Number |
| Sample | (nm) |
| Example 1 of present invention | 5.78 |
| Example 2 of present invention: When the additive was added | 6.88 |
| Comparative Example 1 - Conventional 10 nm or less cerium | 33.6 |
| oxide particles | |
| Comparative Example 2 - Conventional 30 nm cerium oxide | 93.9 |
| particles | |
| Comparative Example 3 - Conventional 60 nm cerium oxide | 138.7 |
| particles | |
| Comparative Example 4 - Cerium oxide particles prepared by | 139.1 |
| calcination method | |

Referring to FIG. 7 and Table 1 above, the cerium oxide particles according to an embodiment of the present invention were found to have a secondary particle size D50 value of about 5.78 nm, which was 10 nm or less. The secondary particle size was about 148% to 199% of the primary particle size measured by TEM in Experimental Example 1 (see FIG. 4), confirming that almost no agglomeration occurred in the slurry and thus the slurry was monodispersed with almost no change in the particle size.

On the other hand, the D50 particle size of the cerium oxide particles of the conventional technology measured by DLS was confirmed to exceed 30 nm, and even in the case of the cerium oxide particles of the 10 nm class, the secondary particle size D50 value measured by DLS was about 336% compared to the primary particle size measured by TEM, and therefore, it was confirmed that the cerium oxide particles of the conventional technology had a much larger secondary particle size, indicating that a lot of agglomeration occurred.

In particular, in the case of cerium oxide particles of 10 nm or less prepared by a supercritical hydrothermal synthesis method or a wet preparation method under basic conditions, it can be confirmed that the secondary particles were very large compared to the size of the primary particles, as the present inventors expected.

In addition, it was confirmed that even when the surface treatment agent, which was an additive, was contained (Example 2), the monodispersity of the cerium oxide particles in the slurry was maintained, and therefore, it was confirmed that the surface treatment agent claimed in the present invention is suitable for use in combination with the cerium oxide particles according to one embodiment of the present invention.

Therefore, it can be seen that the cerium oxide particles according to one embodiment of the present invention have less agglomeration in the slurry than the cerium oxide particles of the conventional technology according to one comparative example, and thus can be dispersed in the slurry in a more monodisperse form.

### Experimental Example 3. X-Ray Diffraction (XRD) Analysis of Cerium Oxide Particles

According to one embodiment of the present invention, the dispersion of Preparation Example 1 was dried at approximately 80 to 90° C. to prepare powder-type cerium oxide particles (primary particles) (Sample A). An analysis of the prepared Sample A was performed using XRD equipment (Rigaku, Ultima IV). At this time, the XRD was set to the conditions of Cu-Kα (λ=1.5418 Å), 40 kV, and 40 mA.

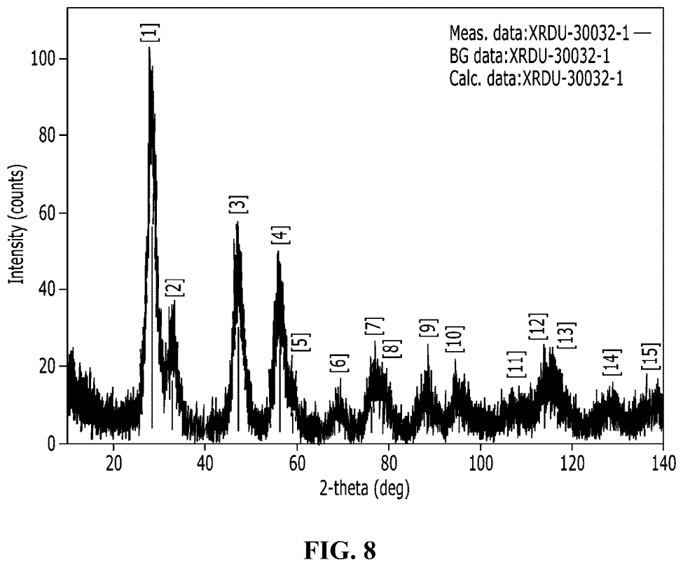

FIG. 8 shows the results of the XRD analysis of the cerium oxide particles according to one embodiment of the present invention.

As a result of the XRD analysis of Sample A, an XRD spectrum (X-axis: 2-theta (degree), Y-axis: intensity) was derived in the form shown in FIG. 8. The crystallite size calculated from the spectrum was 3.25 nm. This is similar to the TEM analysis result of Experimental Example 1, and through this, it was confirmed that the particles of the present invention have the characteristics of single crystals.

### Experimental Example 4. X-Ray Photoelectron Spectroscopy (XPS) Analysis of Cerium Oxide Particles

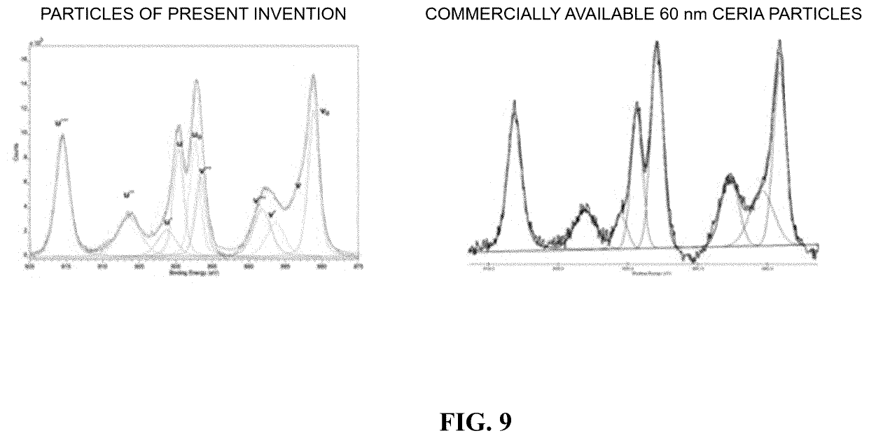

FIG. 9 shows the results of an XPS analysis of the cerium oxide particles according to one embodiment of the present invention and conventional cerium oxide particles having a size of 60 nm. XPS enables to measure the Ce³⁺ and Ce⁴⁺ contents in cerium oxide particles by measuring peaks that appear when the particles are irradiated with soft X-rays at 900.2 to 902.2 eV, 896.4 to 898.4 eV, 885.3 to 887.3 eV, and 880.1 to 882.1 eV, which represent Ce—O bonding energy indicating Ce³⁺, and analyzing the atomic percentage (atomic %) through XPS fitting. Table 2 below shows the XPS result data of the cerium oxide particles according to an embodiment of the present invention.

TABLE 2

| | | | FWHM | Area (P) | | |
|---|---|---|---|---|---|---|
| | Name | Peak BE | eV | CPS · eV | Atomic % | Atomic % |
| Ce³⁺ | u′ | 901.2 | 3.0 | 11,363 | 4.8% | 36.9% |
| | u0 | 897.4 | 1.7 | 26,481 | 11.2% | |
| | v′ | 886.3 | 3.0 | 14,432 | 6.1% | |
| | v0 | 881.1 | 1.7 | 35,248 | 14.8% | |
| Ce⁴⁺ | u″′ | 915.5 | 2.2 | 36,591 | 15.5% | 63.1% |
| | u″ | 906.4 | 3.8 | 20,514 | 8.7% | |
| | U | 899.6 | 1.7 | 25,576 | 10.8% | |
| | v″′ | 896.6 | 1.7 | 19,147 | 8.1% | |
| | v″ | 888.2 | 2.9 | 19,066 | 8.0% | |
| | V | 882.8 | 3.3 | 29,093 | 12.2% | |

As a result of calculating the Ce³⁺ content from the XPS analysis results according to the above-described chemical formula, it can be seen that the Ce³⁺ content was 30% or more. Since Ce³⁺ is a reactive site in the cerium oxide particles, it can be seen that the polishing amount can be increased. Comparative data with the conventional cerium oxide particles obtained by using the above-described method are shown in Table 3.

TABLE 3

| | Ce⁴⁺ | Ce³⁺ |
|---|---|---|
| Sample | Atomic % | Atomic % |
| Example of present invention | 63.1 | 36.9 |
| Comparative Example (Commercially | 86.1 | 13.9 |
| available cerium oxide particles having a size | | |
| of 60 nm) | | |
| Cerium oxide particles having a size of 10 nm | 83.2 | 16.8 |
| or less | | |

As can be seen in Table 3, the cerium oxide particles according to one embodiment of the present invention had a Ce³⁺ content of about 36.9 atomic %, and when compared in Table 3 with the conventional cerium oxide particles having a particle size of 60 nm, which have a Ce³⁺ content of less than 14 atomic %, and with the cerium oxide particles prepared by a hydrothermal synthesis 5 method under supercritical or subcritical conditions having a particle size of 10 nm, which have a Ce³⁺ content of about 16.8%, as known in the literature, it can be confirmed that the particles according to one embodiment of the present invention have a high Ce³⁺ content. When the surface Ce³⁺ content is as high as in the embodiment of the present invention, the polishing rate on a silicon-containing substrate can be increased by a chemical polishing mechanism that forms Si—O—Ce between silica and cerium.

### Experimental Example 5. Confirmation of the Formation of Cerium Oxide Particles Through Fourier Transform Infrared (FT-IR) Spectroscopy

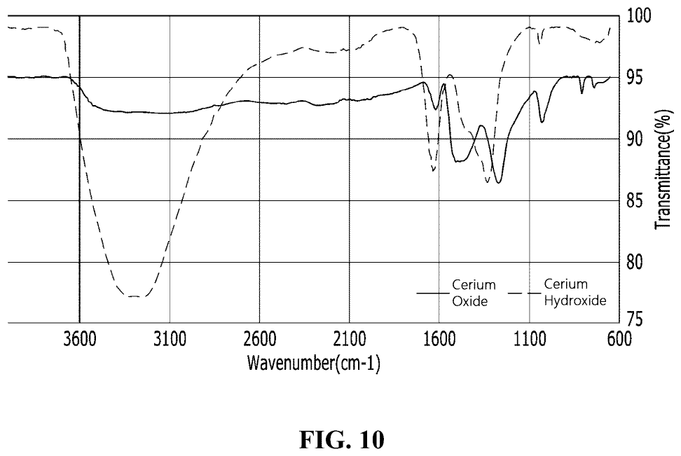

FIG. 10 shows the results of an FT-IR spectroscopy analysis of powder made of cerium oxide particles prepared according to one embodiment of the present invention and powder made of conventional cerium hydroxide particles. The dispersion of Preparation Example 1 according to one embodiment of the present invention was dried at approximately 80 to 90° C. to prepare powder-form cerium oxide particles (primary particles), and then a spectrum was obtained using an FT-IR spectrometer. Scanning was performed once or more within an analysis range of 600 to 4100 cm⁻¹, and a graph was drawn (the wavenumber (cm⁻¹) in the FT-IR spectrum may have an error range of ±10 cm⁻¹).

As a result of analyzing the FT-IR spectroscopy spectrum of FIG. 10, it was confirmed that the infrared transmittance of the powder made of the cerium oxide particles according to one embodiment of the present invention was about 92% to 93% in a range of 3000 cm⁻¹ to 3600 cm⁻¹, and the infrared transmittance in a range of 720 cm⁻¹ to 770 cm⁻¹ was about 93% to 95%. When compared with the FT-IR spectrum of the powder made of the conventional cerium hydroxide particles, which exhibited an infrared transmittance of 75% to 90% in the range of 3000 cm⁻¹ to 3600 cm⁻¹ and an infrared transmittance of 97% to 99% in the range of 720 cm⁻¹ to 770 cm⁻¹, it can be confirmed that the band due to the O—H group of the cerium oxide particles prepared according to one embodiment of the present invention was weaker in the range of 3000 cm⁻¹ to 3600 cm⁻¹ than that of the conventional cerium hydroxide particles, and a peak due to Ce—O stretching appeared in the range of 720 cm⁻¹ to 770 cm⁻¹. Therefore, the above-described results may suggest that the cerium compound prepared according to one embodiment of the present invention is cerium oxide.

It was described above that as a comparative example, among the cerium oxide particles synthesized in a wet manner similar to one embodiment of the present invention, when synthesis is performed under basic conditions, cerium hydroxide may be formed first and then converted into cerium oxide through a post-process. According to the experimental results with reference to FIG. 10, in the case of the particles synthesized under basic pH conditions, the FT-IR measured immediately after synthesis exhibited peaks in the range of 3000 cm⁻¹ to 3600 cm⁻¹ and the range of 720 cm⁻¹ to 770 cm⁻¹, which represented cerium hydroxide, thereby exhibiting the same major peaks of the cerium hydroxide of FIG. 10, and therefore, it is difficult to consider the particles as including only cerium oxide.

### Experimental Example 6. Measurement of Light Transmittance of Slurries Including Cerium Oxide Particles

A slurry composition (Sample A) was prepared in the same manner as in Preparation Example 2, except that the weight ratio of the cerium oxide particles in the CMP slurry was 1% by weight. Meanwhile, slurry compositions were prepared in the same manner as in each of Comparative Examples 1, 2, 3, and 4, except that the weight ratio of the cerium oxide particles in the CMP slurry was 1% by weight (samples B1, B2, B3, and B4 in the order). For each sample, the transmittance for light at 200 to 1100 nm was measured using an ultraviolet-visible (UV-Vis) spectrometer (JASCO).

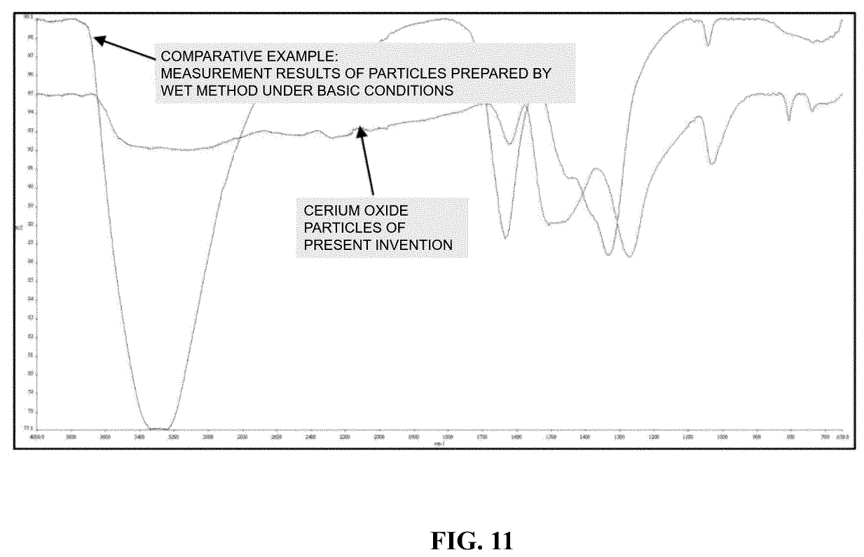

FIG. 11 shows the results of measuring the optical transmittance of slurries including cerium oxide particles according to one embodiment of the present invention and conventional cerium oxide particles of Comparative Examples 1 to 4, using UV-Vis spectroscopy.

Cerium oxide particles according to one embodiment of the present invention and comparative examples were added to deionized water to adjust the polishing agent concentration to 1.0% by weight, and CMP slurries were prepared and analyzed for optical transmittance. At this time, the optical spectrum was measured using a UV-vis spectrometer (JASCO) in a range of 200 to 1,100 nm.

Through the UV-Vis analysis graph, the transmittance (%) of Samples A and A2 and Samples B1 to B4 at each of wavelengths of 500 nm, 600 nm, and 700 nm was summarized and shown in Table 4 below.

TABLE 4

| | Classification | | | | | |
|---|---|---|---|---|---|---|
| | Transmittance (%) | | | | | |
| Wavelength | Sample | Sample | Sample | Sample | Sample | Sample |
| (nm) | A | B1 | B2 | B3 | B4 | A2 |
| 500 | 95.4 | 48.6 | 0.07 | 0.042 | 0.021 | 95.3 |
| 600 | 96.9 | 74.9 | 0.162 | 0.072 | 0.048 | 95.5 |
| 700 | 97.5 | 86.3 | 1.61 | 0.109 | 0.05 | 96.6 |

According to FIG. 11 and Table 4, it was confirmed that the average light transmittance of the slurry including the cerium oxide particles of the present invention was 50% or more for light having a wavelength of 450 to 800 nm. In addition, it was confirmed that the light transmittance was 90% or more for light having a wavelength of about 500 nm and 95% or more for light having a wavelength of about 600 nm and 700 nm.

On the other hand, the light transmittance of the slurries including the conventional cerium oxide particles according to Comparative Examples 1 to 4 (conventional cerium oxide particles having a particle size of 10 nm, 30 nm, or 60 nm and ceria particles prepared by calcination method) was measured. Comparative Example 4 (calcined ceria particles) exhibited a light transmittance of almost 0%, and the average light transmittance of the Comparative Example 1 slurry including the commercially available conventional cerium oxide particles having a size of 10 nm was less than 80%, and the light transmittance at a wavelength of 500 nm was less than 50%. The primary particle size of Comparative Examples 2 and 3 was coarse as 30 and 60 nm, respectively, and their secondary particle size was also coarse (i.e., the agglomeration was high in the slurries) compared to the examples of the present invention, and thus the transmittance in the visible light range was only less than 20%.

On the other hand, it was confirmed that the cerium oxide particles according to one embodiment of the present invention exhibited a light transmittance of 90% or more in the visible light range, which means that the cerium oxide particles of the present invention had a fine primary particle size, and agglomeration into secondary particles occurred less than in the cerium oxide particles of the conventional technology. It is well known that when the secondary particles exceed 20 nm, the opacity of the slurry composition may usually be observed even visually, and the light transmittance may be less than 80% in the visible light range wavelength.

According to the slurry composition of the present invention, when the primary particle size of the cerium oxide particles is small and the agglomeration into secondary particles is little, the dispersion stability is high so that the particles may be uniformly distributed, and since the number of particles in contact with a wafer increases, the oxide film polishing rate can be excellent. In addition, since the particles themselves are fine, it can be easily predicted that when polishing a polishing target film using the slurry composition containing the particles, the probability of defects such as scratches occurring on the surface will be reduced.

In addition, it can be confirmed that even when the surface treatment agent is contained as an additive, the light transmittance of the present invention are maintained at the same level. Considering that when an additive is incorrectly selected, the monodispersity of the cerium oxide particles according to one embodiment of the present invention in a slurry may be deteriorated, the results show that the surface treatment agent selected in the present invention can satisfy the required properties without deteriorating the basic particle properties in the slurry.

### Experimental Example 7. Comparison of Oxide Polishing Rate of Cerium Oxide Particles

The slurry compositions of Preparation Examples 2-1 and 2-4 according to one embodiment of the present invention were each prepared as samples.

Polishing of an oxide wafer using the samples was carried out using a polisher (Reflexion®LK CMP, Applied Materials). Specifically, a plasma enhanced-tetraethyl orthosilicate (PE-TEOS) silicon oxide wafer (300 mm PE-TEOS Wafer) was placed on a platen, and the surface of the wafer was brought into contact with a pad (IC1010, DOW) of the polisher. Thereafter, the slurry composition of the sample was supplied at a rate of 200 mL/min, and the polishing process was performed while rotating the platen and the pad of the polisher. At this time, the rotation speed of the platen and the rotation speed of the head were 67 rpm/65 rpm, the polishing pressure was 2 psi, and the polishing time was 60 seconds. Meanwhile, the silicon oxide film thickness of the wafer was measured using ST5000 (Spectra Thick 5000ST, K-MAC). The results are shown in Table 5 below.

TABLE 5

| | Preparation | Preparation | Preparation | Preparation |
|---|---|---|---|---|
| | Example 2-1 | Example 2-2 | Example 2-3 | Example 2-4 |
| Cerium oxide | Particles of the | Particles of the | Particles of the | Particles of the |
| | present invention | present invention | present invention | present invention |
| Cerium oxide | 0.05% | 0.05% | 0.05% | 0.05% |
| content | | | | |
| pH | 5.5 | 8.0 | 9.0 | 10.0 |
| PETEOS | 3,458 Å/min | Precipitation | Precipitation | Precipitation |
| removal rate | | | | |
| | Preparation | Preparation | Preparation | Preparation |
| | Example 3-1 | Example 3-2 | Example 3-3 | Example 3-4 |
| Cerium oxide | Particles of the | Particles of the | Particles of the | Particles of the |
| | present invention | present invention | present invention | present invention |
| Cerium oxide | 0.05% | 0.05% | 0.05% | 0.05% |
| content | | | | |
| pH | 5.5 | 8.0 | 9.0 | 10.0 |
| PETEOS | 2,548 Å/min | 1,985 Å/min | 1,255 Å/min | 846 Å/min |
| removal rate | | | | |

As shown in Table 5, when the slurry composition of the example is used, in the case of Preparation Example 2 where surface treatment was not performed, it can be seen that precipitation occurs at pH 8.0 or higher. However, in the case of Preparation Example 3 where surface treatment was performed with a surface treatment agent, it can be seen that a relatively high oxide film removal rate was achieved even at a high pH.

### Experimental Example 8. Defect Evaluation of Cerium Oxide Particles

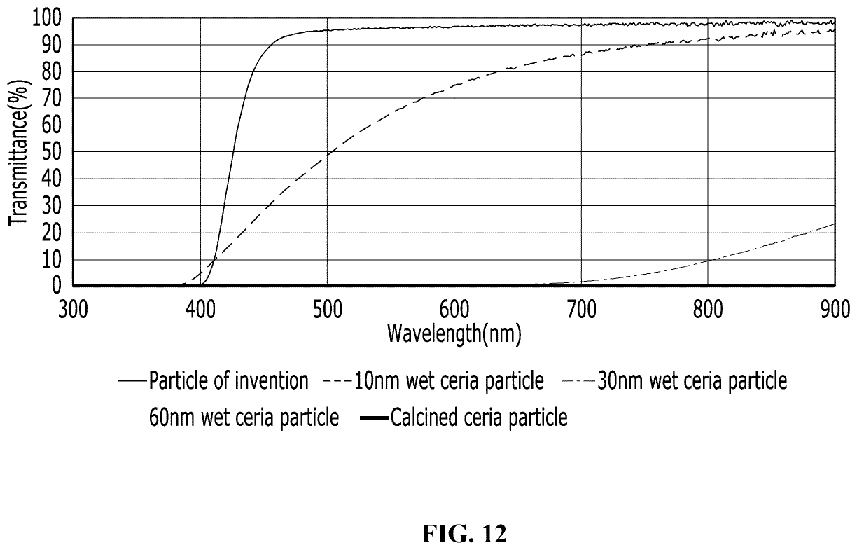

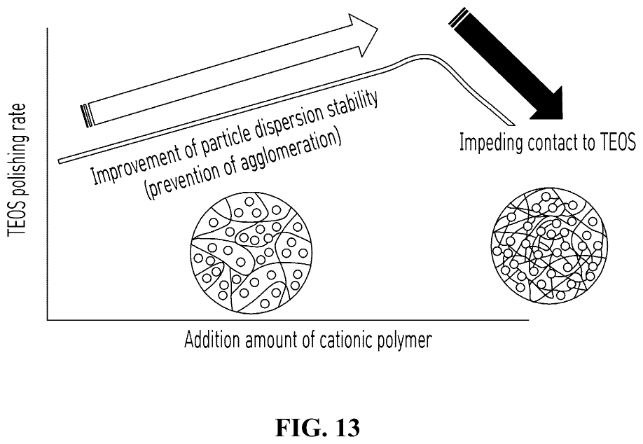

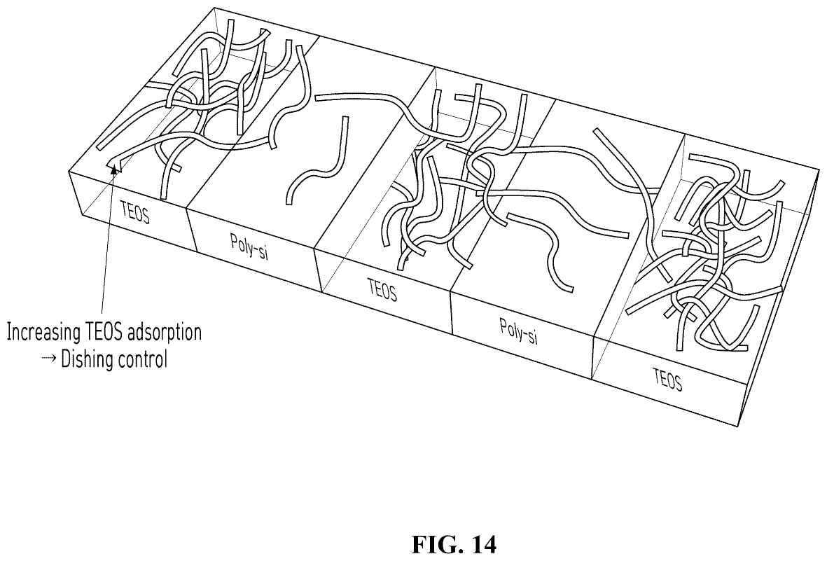

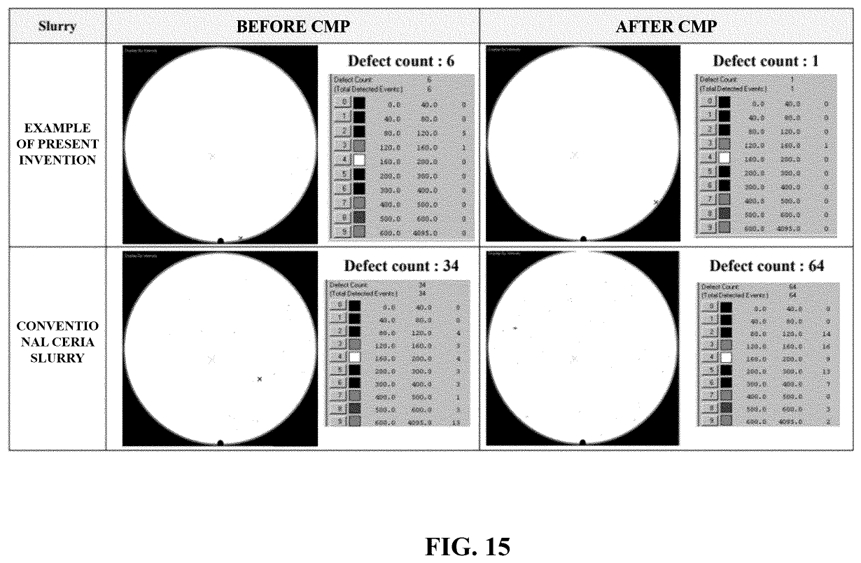

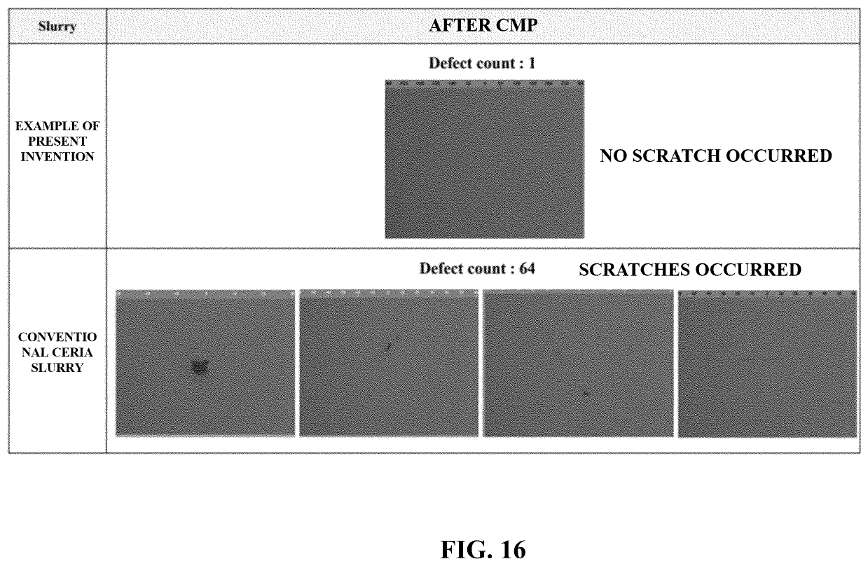

FIGS. 12 and 13 show scanned images of an oxide wafer before and after CMP using a CMP slurry composition including the cerium oxide particles according to one embodiment of the present invention and a CMP slurry composition including cerium oxide particles having a size of 60 nm.

A surface analysis of the oxide wafer was carried out using a full wafer scan method using AIT-XP equipment.

Referring to FIGS. 12 and 13, as a result of analyzing the surface of the oxide wafer that had undergone CMP using a CMP slurry composition including the cerium oxide particles according to one embodiment of the present invention before and after CMP, the number of defects before CMP was counted as 6 and the number of defects after CMP was counted as 1. Therefore, it was confirmed that the defects on the surface of an oxide wafer were reduced after CMP using an embodiment of the present invention, and that no scratches occurred on the surface of the wafer during the CMP process. On the other hand, as a result of analyzing the surface of an oxide wafer that had undergone CMP using a CMP slurry composition including the cerium oxide particles of the conventional technology before and after CMP, the number of defects increased from 34 before CMP to 64 after CMP, confirming that the cerium oxide particles of the conventional technology caused scratches on the surface of the wafer. These results suggest that since the size of the cerium oxide particles according to one embodiment of the present invention is smaller than that of the cerium oxide particles of the conventional technology, the probability of occurrence of defects on the surface of the oxide wafer, which is a polishing target, can be significantly reduced. In addition, in the case of the cerium oxide particles according to one embodiment of the present invention, they are monodispersed in the slurry and are fine particles in themselves, and therefore, it may be sufficiently predicted that defects are minimized even when an additive is included.

### Experimental Example 9. Analysis of Zeta Potential Change According to Addition of Surface Treatment Agent

TABLE 6

| | Preparation | Preparation | Preparation | Preparation |
|---|---|---|---|---|
| | Example 2-1 | Example 2-2 | Example 2-3 | Example 2-4 |
| Cerium oxide | Particles of the | Particles of the | Particles of the | Particles of the |
| | present invention | present invention | present invention | present invention |
| Cerium oxide | 0.05% | 0.05% | 0.05% | 0.05% |
| content | | | | |
| pH | 5.5 | 8.0 | 9.0 | 10.0 |
| Zeta Potential | 34.4 | 0 | 0 | 0 |
| (mV) | | | | |
| | Preparation | Preparation | Preparation | Preparation |
| | Example 3-1 | Example 3-2 | Example 3-3 | Example 3-4 |
| Cerium oxide | Particles of the | Particles of the | Particles of the | Particles of the |
| | present invention | present invention | present invention | present invention |
| Cerium oxide | 0.05% | 0.05% | 0.05% | 0.05% |
| content | | | | |
| pH | 5.5 | 8.0 | 9.0 | 10.0 |
| Zeta Potential | −8.5 | −11.5 | −17.6 | −24.4 |
| (mV) | | | | |

Referring to Table 6 above, it can be confirmed that when the surface treatment agent according to one embodiment of the present invention is contained, the zeta potential of the cerium oxide particles is converted to a negative value. This is noteworthy in that it is an effect that can be obtained without damaging other properties of the particles according to one embodiment of the present invention in the slurry.

What is claimed is:

1. A chemical mechanical polishing slurry composition comprising:
cerium oxide particles;
a solvent; and
a surface treatment agent,
wherein the surface treatment agent converts a zeta potential of the cerium oxide particle surface to a negative value, and
the average light transmittance in a wavelength range of 450 to 800 nm is 50% or more in an aqueous dispersion in which a content of the cerium oxide particles is adjusted to 1.0% by weight.

2. The chemical mechanical polishing slurry composition of claim 1, wherein the cerium oxide particles have a zeta potential of 1 to 80 mV in a range of pH 2 to 8 before the surface treatment agent is added.

3. The chemical mechanical polishing slurry composition of claim 1, wherein the cerium oxide particles have a zeta potential of −80 to −1 mV in a range of pH 7 to 10 after the surface treatment agent is added.

4. The chemical mechanical polishing slurry composition of claim 1, wherein the content of the surface treatment agent is 0.001% to 1% by weight based on the total weight of the chemical mechanical polishing slurry composition.

5. The chemical mechanical polishing slurry composition of claim 1, wherein the surface treatment agent is at least one selected from hydroxyl ethylidene (1,1-diphosphonic acid) (HEDP), aminotrimethylenephosphonic acid (ATMP), 2-phosphonobutane 1,2,4-tricarboxylic acid (PBTC), ethylenediamine tetramethylene phosphonic acid (EDTMP), nitrilo-3-acetic acid, diethylenetriamine-5 acetic acid (DTPA), N-(2-hydroxyethyl)ethylenediamine-N,N′,N′-3-acetic acid (HEDTA), triethylenetetramine-6-acetic acid, 1,3-propanediamine-4-acetic acid, 1,3-diamino-2-propenol-N,N,N′,N′-4-acetic acid, N-(2-hydroxyethyl) imino-2-acetic acid, dihydroxy ethylglycine (DHEG), glycol ether diamine-4-acetic acid, propylenediamine tetraacetate (PDTA), ethylenediaminetetraacetate (EDTA), and salts thereof.

6. The chemical mechanical polishing slurry composition of claim 1, wherein the surface treatment agent is hydroxyl ethylidene (1,1-diphosphonic acid) (HEDP) or ethylenediaminetetraacetate (EDTA).

7. The chemical mechanical polishing slurry composition of claim 1, wherein the cerium oxide particles are included in an amount of 0.001% to 5% by weight based on the total weight of the chemical mechanical polishing slurry composition.

8. The chemical mechanical polishing slurry composition of claim 1, further comprising a pH adjuster,
wherein the pH adjuster is one or more inorganic acids selected from the group consisting of sulfuric acid, hydrochloric acid, nitric acid, and phosphoric acid,
one or more organic acids selected from the group consisting of acetic acid, citric acid, glutaric acid, gluconic acid, formic acid, lactic acid, malic acid, malonic acid, maleic acid, oxalic acid, phthalic acid, succinic acid, and tartaric acid,
one or more amino acids selected from the group consisting of lysine, glycine, alanine, arginine, valine, leucine, isoleucine, methionine, cysteine, proline, histidine, phenylalanine, serine, tricine, tyrosine, aspartic acid, tryptophan, and aminobutyric acid,
imidazole, alkyl amines, alcohol amines, quaternary amine hydroxides, ammonia, or a combination thereof.

9. The chemical mechanical polishing slurry composition of claim 1, wherein the composition has a pH of 2 to 10.

10. The chemical mechanical polishing slurry composition of claim 1, wherein the chemical mechanical polishing slurry composition has a silicon oxide film polishing rate of 1,000 to 5,000 Å/min.

11. The chemical mechanical polishing slurry composition of claim 1, wherein the cerium oxide particles have a secondary particle size measured by dynamic light scattering (DLS) particle size analyzer of 1 to 20 nm.

12. The chemical mechanical polishing slurry composition of claim 1, wherein the cerium oxide particles have a primary particle size measured by transmission electron microscopy (TEM) of 0.5 to 10 nm.

13. The chemical mechanical polishing slurry composition of claim 1, wherein, when analyzing by X-ray photoelectron spectroscopy (XPS), the sum of the XPS peak areas representing the Ce—O binding energy of Ce³⁺ is 30% or more compared to the total sum of 100% of the XPS peak areas representing the Ce—O binding energy of the cerium oxide particle surface.

14. The chemical mechanical polishing slurry composition of claim 1, wherein the cerium oxide particles are prepared by a step of obtaining a dispersion of particles by precipitating them at an acidic pH in a solution including a raw material precursor.

15. A method of manufacturing a semiconductor device, the method comprising a step of polishing by using the chemical mechanical polishing slurry composition of claim 1.
